(19) United States
(12) Patent Application Publication
(10) Pub. No.: US 2009/0233221 A1
(43) Pub. Date: Sep. 17, 2009

(54) NEGATIVE-WORKING PHOTOSENSITIVE MATERIAL AND NEGATIVE-WORKING PLANOGRAPHIC PRINTING PLATE PRECURSOR

(75) Inventors: Shigefumi KANCHIKU, Haibara-gun (JP); Toyohisa OYA, Haibara-gun (JP); Keisuke ARIMURA, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/402,276

(22) Filed: Mar. 11, 2009

(30) Foreign Application Priority Data
Mar. 13, 2008 (JP) 2008-064721
Aug. 29, 2008 (JP) 2008-221786

(51) Int. Cl. G03F 7/004

(52) U.S. Cl. 430/270.1

(57) ABSTRACT

The present invention provides a negative-working photosensitive material formed by sequentially layering an undercoat layer and a photosensitive layer on a support, wherein the undercoat layer contains a polymer containing (a) a structural unit containing at least one selected from a carboxylic acid or a carboxylic acid salt and (b) a structural unit containing at least one carboxylic acid ester; the photosensitive layer contains (A) an infrared absorbent, (B) an organoboron compound, (C) an onium salt compound and (D) a compound having a polymerizable unsaturated group; and a ratio of (a) with respect to (a) and (b) is 30 to 90% by mol. The invention also provides a negative-working planographic printing plate precursor that uses the negative-working photosensitive material.

### CROSS-REFERENCE TO RELATED APPLICATION

This application claims priority under 35 USC 119 from Japanese Patent Applications Nos. 2008-064721 and 2008-221786 the disclosures of which are incorporated by reference herein.

### BACKGROUND OF THE INVENTION

1. Field of the Invention

The present invention relates to a negative-working photosensitive material and a negative-working planographic printing plate precursor including the material. In particular, the invention relates to a negative-working photosensitive material which allows direct drawing by infrared laser light, and a negative-working planographic printing plate precursor including the material.

2. Description of the Related Art

Conventionally, a PS plate having a lipophilic photosensitive resin layer provided on a hydrophilic support has been widely used as a planographic printing plate precursor, and a desired printing plate is obtained by a plate-making method which usually involves mask exposure (surface exposure) via a lithographic film and then removal of non-image regions by dissolving. In recent years, digitalization techniques which involve electronic processing, accumulation and output of image information using computers have been spreading. A wide variety of new image output systems compatible with such digitalization techniques have come to be used in practical applications. As a result, there has been demand for computer-to-plate (CTP) techniques of producing a printing plate directly by scanning a highly directional light, such as laser light, according to digitalized image information, without employing a lithographic film. A critical technical issue has been the provision of a planographic printing plate precursor suitable for these techniques.

As a planographic printing plate precursor capable of such scanning exposure to light, a planographic printing plate precursor has been proposed which includes, on a hydrophilic support, a lipophilic photosensitive resin layer (hereinafter also referred to simply as a photosensitive layer) including a photosensitive compound capable of generating active species such as radicals or Bronsted acids by laser exposure, and has already been put on the market. When the planographic printing plate precursor is scanned with laser based on digital information, active species are generated. The action of the active species causes physical or chemical changes at the photosensitive layer, making the photosensitive layer insoluble, and by then developing the photosensitive layer, a negative planographic printing plate is obtained. A specific example thereof is a negative-working planographic printing plate precursor having, on a hydrophilic support, a photopolymerizable photosensitive layer including a photopolymerization initiator excellent in photosensitive speed, an ethylenically unsaturated compound capable of addition polymerization, and a binder polymer soluble in an alkali developer. The planographic printing plate precursor has the advantages of being excellent in productivity, convenient for development processing and having favorable resolution and ink affinity and, therefore, has a desirable printing performance.

In this kind of negative-working planographic printing plate precursor, in order to improve the adhesion between the photosensitive layer and the support, and the development removability of an unexposed portion of a photosensitive layer, an undercoat layer is usually provided between the support and the photosensitive layer (see for example, JP-A No. 2001-272787). However, depending on the state of the support, particularly when a support surface is roughened to improve the printing durability, the development removability of an unexposed portion of a photosensitive layer has been insufficient.

Furthermore, it is known to use a high molecule compound having an acid group as an undercoat layer (see, for example, JP-A No. 2005-99113). Herein, an example where, in the case where a high molecule compound having sulfonic acid or carboxylic acid as an acid group is used in an intermediate layer and the acid group has a sulfonic acid in a side chain as an acid group, an example where an alkali metal salt, an ammonium salt or a water-soluble amine salt is formed is disclosed. However, in such an intermediate layer, there is still room for further improving the adhesiveness between a substrate and a photosensitive layer, and the printing resistance in a formed image area also cannot be considered to be sufficient for practical use.

Still furthermore, a technology where a combination of a specified polymerization initiator and a binder polymer is used in a photosensitive layer to achieve high sensitivity is proposed (see, for example, WO2005/064402). However, the photosensitive layer as well is not said sufficient in suppressing a residual film in an unexposed region. Accordingly, an improvement in the development removability is in demand.

The present inventors, after studying hard to overcome the foregoing problems, found that a negative-working photosensitive material provided with an undercoat layer containing a specified polymer overcomes the problems and completed the invention.

That is, a configuration of the invention is as shown bellow.

### SUMMARY OF THE INVENTION

The present invention has been made in view of the above circumstances and provides a negative-working photosensitive material and a negative-working planographic printing plate precursor.

A first aspect of the invention provides a negative-working photosensitive material formed by sequentially layering an undercoat layer and a photosensitive layer on a support, wherein:

the undercoat layer contains a polymer containing (a) a structural unit containing at least one selected from a carboxylic acid or a carboxylic acid salt and (b) a structural unit containing at least one carboxylic acid ester;

the photosensitive layer contains (A) an infrared absorbent, (B) an organic boron compound, (C) an onium salt compound and (D) a compound having a polymerizable unsaturated group: and

a ratio of (a) the structural unit containing at least one selected from a carboxylic acid or a carboxylic acid salt in the polymer containing (a) the structural unit containing at least one selected from a carboxylic acid or a carboxylic acid salt and (b) the structural unit containing at least one carboxylic acid ester is 30 to 90% by mol.

A second aspect of the present invention provides a negative-working planographic printing plate precursor that is formed with the negative-working photosensitive material of the first aspect of the present invention.

### DETAILED DESCRIPTION OF THE INVENTION

According to the invention, a negative-working photosensitive material that hardly undergoes the polymerization inhibition by oxygen, is capable of forming an image at high sensitivity by infrared exposure, is improved in the developability in a non-image area and the adhesiveness with a substrate and is capable of combining the stain resistance and printing durability during printing; and a negative-working planographic printing plate precursor that uses the negative-working photosensitive material.

In the specification, when one or both of “acrylate, methacrylate” and one or both of “acryl, methacryl” are expressed, these are described in some cases as “(meth)acrylate” and “(meth)acryl”, respectively.

<Negative-Working Photosensitive Material>

A negative-working photosensitive material of the invention will be detailed.

The negative-working photosensitive material of the invention is a negative-working photosensitive material formed by sequentially layering an undercoat layer and a photosensitive layer on a support, wherein the undercoat layer contains a polymer containing (a) a structural unit containing at least one selected from a carboxylic acid or a carboxylic acid salt and (b) a structural unit containing at least one carboxylic acid ester, and the photosensitive layer contains (A) an infrared absorbent, (B) an organic boron compound, (C) an onium salt compound and (D) a compound having a polymerizable unsaturated group.

Herein, the phrase “sequentially layered” means that an undercoat layer and a photosensitive layer are disposed on a support in this order. The phrase does not exclude the presence of another layer (such as an intermediate layer, a backcoat layer, or an overcoat layer) which may be disposed depending on the purpose.

<Undercoat Layer>

In the beginning, an undercoat layer will be described.

An undercoat layer in a negative-working photosensitive material of the invention includes a polymer (which may be hereinafter referred to as a “specified polymer”) including a structural unit (a) containing at least one of a carboxylic acid or a carboxylic acid salt (which may be hereinafter referred to as a “structural unit (a)”) and a structural unit (b) containing at least one carboxylic acid ester (which may be hereinafter referred to as a “structural unit (b)”, the content of the structural unit (a) in the specified polymer being from 30% to 90% by mole.

Structural unit (a) containing at least one of carboxylic acid or carboxylic acid salt

The structural unit (a) is preferably a structural unit represented by the following formula (a).

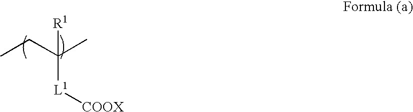

In the formula (a), R¹ represents a hydrogen atom, a substituent having 1 to 30 carbon atoms, or a halogen atom, X represents a hydrogen atom or a counter cation that is necessary to neutralize a charge, and L¹ represents a single bond or a divalent linking group.

Examples of the substituent which is represented by R¹ and has 1 to 30 carbon atoms include a methyl group, an ethyl group, a propyl group, a butyl group, a pentyl group, a hexyl group, a cyclohexyl group, a methoxy group, an ethoxy group, a butoxy group, an acetoxy group, a propionyloxy group, a methoxycarbonyl group, an ethoxycarbonyl group, and a cyano group. Examples of the halogen atom represented by R¹ include a fluorine atom, a chlorine atom, a bromine atom, and an iodine atom.

R¹ in the formula (a) more preferably represents a hydrogen atom, a methyl group, a fluorine atom, or a chlorine atom, and particularly preferably represents a hydrogen atom or a methyl group.

Examples of the divalent linking group represented by L¹ include an alkylene group, an arylene group, a carbonyl group, —CR₂—, —O—, —C═O—, —S—, —S═O—, —S(═O)₂—, —NR—, a vinylene group, a phenylene group, a cycloalkylene group, a naphthylene group, a biphenylene group and a combination of these structural units, wherein R represents a hydrogen atom or a substituent. More preferable examples of L¹ include a single bond, —O(CH₂)ₚ—, NH(CH₂)_{q}—, COO(CH₂)ᵣ—, —CONH(CH₂)ₛ— (wherein p, q, r, and s each represent an integer of from 0 to 20), and a phenylene group. Particularly preferable examples of L¹ include a single bond, —COO—, —CONH—, and a phenylene group, and a single bond is most preferred.

Furthermore, in the case where X represents a hydrogen atom, a structural unit (a) becomes a structural unit containing a carboxylic acid, and in the case where X represents a counter cation necessary to neutralize electric charge, a structural unit (a) becomes a structural unit containing a carboxylic acid salt.

As the counter cation represented by X and necessary to neutralize electric charge, known arbitrary counter cations may be used. Although an inorganic cation is usually preferably used, in some cases, an organic cation is preferably used from the viewpoint of imparting solubility in an organic solvent.

As preferable examples of inorganic cation, metal ions and ammonium ion are cited. Preferable specific examples thereof include an alkali metal ion (such as an ion of each of lithium, sodium and potassium), a metal ion of periodic table 2 group (such as an ion of each of magnesium, calcium, strontium and barium), other metal ion (such as an ion of each of aluminum, titanium, iron and zinc) and an ammonium ion, and a sodium ion, a potassium ion and a lithium ion are particularly preferably cited.

Preferable examples of organic cation include an organic ammonium ion (such as an ion of each of methylammonium, ethylammonium, diethylammonium, dimethylammonium, trimethylammonium, triethylammonium, tetraethylammonium, tetramethylammonium and tetrabutylammonium) and an ion containing alkylated heteroring (ion of each of pyridinium, morpholinium and guanisium). An organic ammonium ion is more preferably cited and particularly preferable specific examples thereof include a tetramethylammonium ion, a tetraethylammonium ion and a tetrabutylammonium ion.

In what follows, specific examples of the structural unit (a) will be shown below. However, the invention is not restricted thereto.

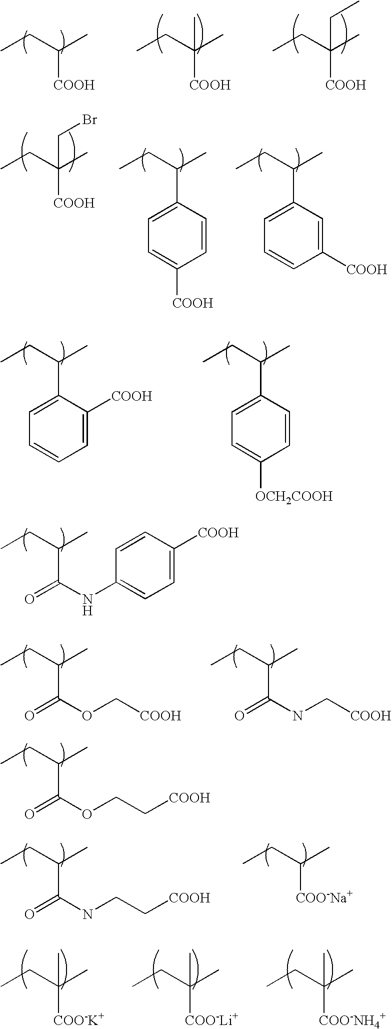

[(b) Structural Unit Containing at Least One Carboxylic Acid Ester]

The structural unit (b) preferably has a structure represented by a formula (b) shown below.

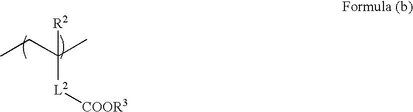

In the formula (b), R² represents a hydrogen atom, a substituent having 1 to 30 carbon atoms, or a halogen atom; R³ represents a substituent having 1 to 30 carbon atoms; and L² represents a single bond or a divalent linking group. Examples of the divalent linking groups represented by L² include an alkylene group, an arylene group, a carbonyl group, —CR₂—, —O—, —C═O—, —S—, —S═O—, —S(═O)₂—, —NR—, a vinylene group, a phenylene group, a cycloalkylene group, a naphthylene group, a biphenylene group (wherein R represents a hydrogen atom or a substituent), and a combination of these structural units. L² most preferably represents a single bond.

Examples of the substituent which is represented by R² and has 1 to 30 carbon atoms include a methyl group, an ethyl group, a propyl group, a butyl group, a pentyl group, a hexyl group, a cyclohexyl group, a methoxy group, an ethoxy group, a butoxy group, an acetoxy group, a propionyloxy group, a methoxycarbonyl group, an ethoxycarbonyl group, and a cyano group. Examples of the halogen atom include a fluorine atom, a chlorine atom, a bromine atom, and an iodine atom. R² more preferably represents a hydrogen atom, a methyl group, an ethyl group, a fluorine atom, or a chlorine atom, and particularly preferably represents a hydrogen atom or a methyl group.

Furthermore, examples of the substituent which is represented by R³ and has 1 to 30 carbon atoms include alkyl groups (such as a methyl group, an ethyl group, a propyl group, an isopropyl group, a butyl group, a hexyl group, an octyl group, a cyclohexyl group, a 2-ethylhexyl group, a benzyl group, a 2-hydroxyethyl group, and a 2-methoxyethyl group) and aryl groups (such as a phenyl group, a 4-methoxyphenyl group, and a naphthalenyl group). More preferable examples thereof include a methyl group, an ethyl group, a propyl group, an isopropyl group, a butyl group, a hexyl group, an octyl group, a cyclohexyl group, a 2-ethylhexyl group, a benzyl group, a 2-hydroxyethyl group, and a 2-methoxyethyl group. Particularly preferable examples thereof include a methyl group, an ethyl group, a propyl group, an isopropyl group, a butyl group, a hexyl group, a 2-ethylhexyl group, a 2-hydroxyethyl group, and a 2-methoxyethyl group, and most preferable examples thereof include an alkyl group having 1 to 3 carbon atoms.

Hereinafter, specific examples of the structural units (b) will be shown. However, the invention is not limited thereto.

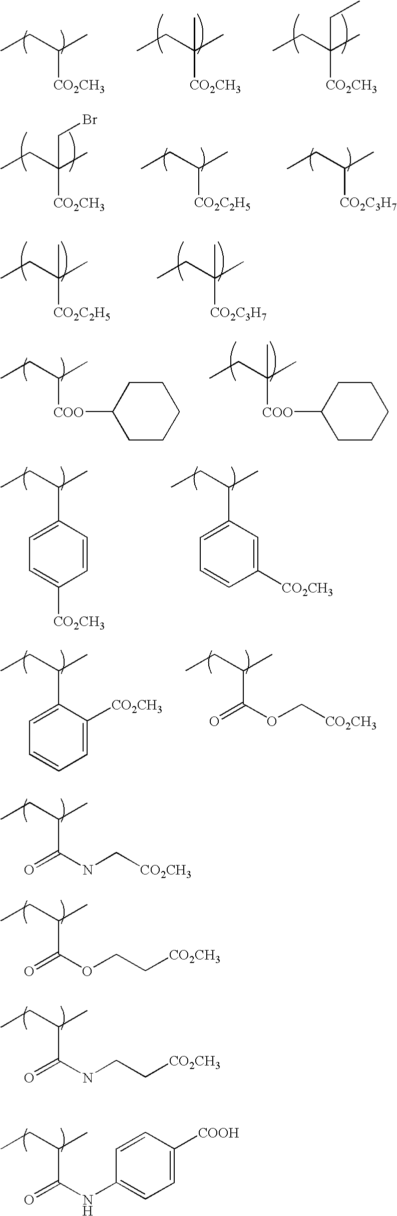

A ratio of the structural unit (a) in the specified polymer is preferably from 30 to 90% by mol, more preferably from 30 to 80% by mol and still more preferably from 35 to 70% by mol. When a ratio of the structural unit (a) is in the range, the stain resistance and printing durability at the time of printing may be combined.

On the other hand, the content of the structural units (b) with respect to the total structural units in the polymer is preferably from 1% to 70% by mole, more preferably from 20% to 70% by mole, and still more preferably from 30% to 65% by mole.

Furthermore, carboxylic acid of the structural unit (a) may be neutralized. The degree of neutralization at that time may be set in the range of 0 to 100%. However, the degree of neutralization is preferably from 20 to 80% and more preferably from 30 to 60%. When the carboxylic acid in the structural unit (a) is neutralized, the carboxylic acid is inhibited from eluting into a solvent (solvent of photosensitive layer coating solution) that is used to coat a photosensitive layer described below.

On the other hand, it is preferable that the specified polymer is substantially free from acid other than carboxylic acid. Herein, the phrase “substantially free from acid other than carboxylic acid” means that the polymer units do not contain 5% by mole or more of acid other than carboxylic acid. In the specified polymer, the content of acid other than carboxylic acid is preferably 3% by mole or less and more preferably 2% by mole or less. When the specified polymer is substantially free from acid other than carboxylic acid, the effect of stain resistance during printing becomes pronounced.

The weight average molecular weight of the specified polymer is preferably from 5,000 to 200,000, more preferably from 8,000 to 150,000, and still more preferably from 10,000 to 100,000. The method of measuring the weight average molecular weight is not particularly limited, and well known methods can be used. However, gel permeation chromatography (GPC) is preferably used.

In what follows, as specific examples of the specified polymer, exemplified compounds: (a-1) to (a-10) are shown without restricting the invention thereto. In the specific examples shown below, Mw represents a weight average molecular weight of the specified polymer, and a numerical value next to ( ) representing a structural unit represents a molar ratio (mol %) of the structural unit. The weight average molecular weight is a value obtained by measuring with a GPC method detailed below.

### (Measurement of Average Molecular Weight by Gel Permeation Chromatography (GPC))

The weight-average molecular weight of a polymer was measured by the following method, with PEG (manufactured by Tosoh Corporation) as a reference sample.

### Column: Shodex Ohpak SB-806M HQ 8×300 mm

Shodex Ohpak SB-806M HQ 8×300 mm

Shodex Ohpak SB-802.5 HQ 8×300 mm

Mobile phase: Solution of 50 mM disodium hydrogen phosphate (acetonitrile/water=1/9)
Flow rate: 0.8 ml/min

### Detector: RI

Charge amount: 100 μl
Sample concentration: 0.1% by mass

(Shodex: registered trade mark, manufactured by Showa Denko K. K.)

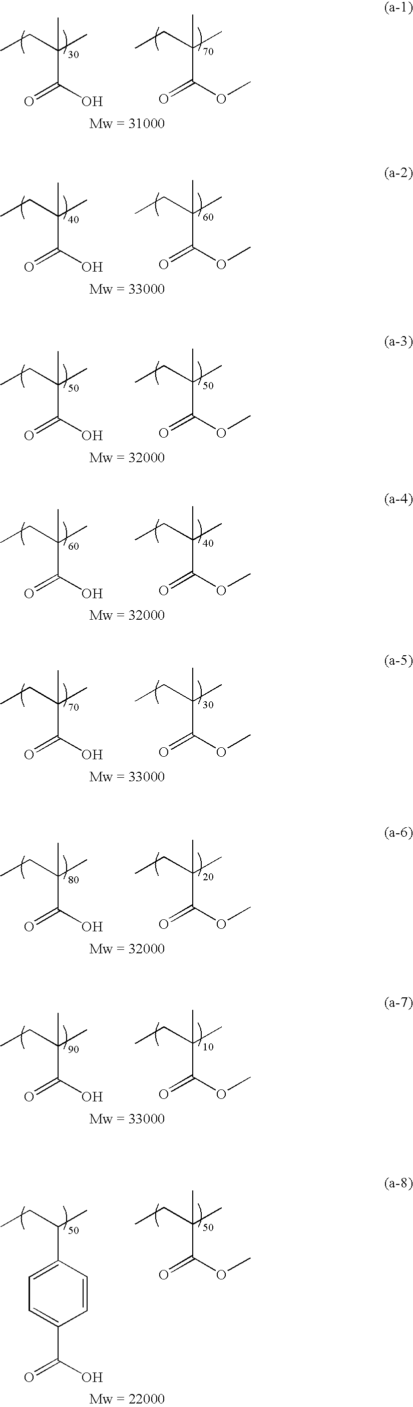

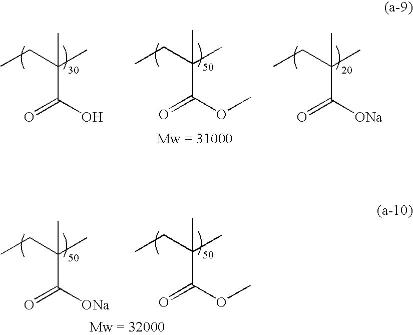

An undercoat layer may be formed by coating an undercoat layer coating solution containing the specified polymer on a support. A coating amount of an undercoat layer coating solution is preferably from 1 to 1000 mg/m², more preferably from 1 to 50 mg/m² and still more preferably from 5 to 20 mg/m². When the coating amount is in the range, the scumming is effectively inhibited from occurring and a sufficient improvement in the printing durability is obtained.

Furthermore, in the undercoat layer coating solution, optional components, for example, a pH adjusting agent such as phosphoric acid, phosphorous acid, hydrochloric acid or low molecule organic sulfonic acid and a wetting agent such as saponin may be added.

<Support>

The support to be used in the negative-working photosensitive material of the invention may be a support that has been subjected to hydrophilicity-imparting treatment as will be described later. Examples of the support include paper, a polyester film, and an aluminum plate. Of these, an aluminum plate is preferable since the plate has excellent dimensional stability, is relatively inexpensive, and can be provided with excellent surface hydrophilicity and strength by an optional surface treatment. A composite sheet in which an aluminum sheet is bonded onto a polyethylene terephthalate film as described in JP-B No. 48-18327 may also be used as the support.

An aluminum plate most suitable as a support in the invention is a metal plate mainly made of dimensionally stable aluminum and selected from a pure aluminum plate, an alloy plate mainly made of aluminum and containing foreign elements slightly or a plastic film or paper on which aluminum (alloy) is laminated or deposited. In the following description, above-cited support made of aluminum or aluminum alloy is used by generically referring to as an aluminum support. Examples of the foreign elements contained in the aluminum alloy include silicon, iron, manganese, copper, magnesium, chromium, zinc, bismuth, nickel and titanium and a content of the foreign elements in the alloy is 10% by mass or less. In the invention, a pure aluminum plate is preferred. However, it is difficult to produce pure aluminum from the viewpoint of refining technology; accordingly, the aluminum plate slightly containing foreign elements may be used. The aluminum plate applied to the invention is not particularly specified in the composition thereof as mentioned above and so far known materials such as JIS A 1050, JIS A 1100, JIS A 3103 an JIS A 3005 may be appropriately used.

The thickness of the aluminum support used in the invention is from about 0.1 to about 0.6 mm. The thickness may be appropriately changed in accordance with the size of the printing machine, the size of the printing plate, and user's request.

The aluminum support may be subjected to a surface treatment described below, so as to be made hydrophilic.

The aluminum support like this is subjected to surface treatment described below to render hydrophilic.

[Surface-Roughening Treatment]

The surface-roughening treatment may be a mechanical treatment as disclosed in JP-A No. 56-28893, chemical etching, electrolytic graining, or the like. The surface-roughening treatment may also be an electrochemical surface-roughening method of roughening the support surface electrochemically in a hydrochloric acid or nitric acid electrolyte, or a mechanical surface-roughening method such as a wire brush graining method of brushing the surface of aluminum with a metallic wire, a ball graining method of polishing the surface of aluminum with polishing beads and a polishing agent or a brush graining method of roughening the surface with a nylon brush and a polishing agent. One of these surface-roughening methods may be used alone, or two or more of them may be used in combination. Of these methods, a method useful for the surface-roughening is the electrochemical surface-roughening method of roughening the support surface electrochemically in a hydrochloric acid or nitric acid electrolyte. The electric quantity suitable for the method is from 50 to 400 C/dm², when the support serves as an anode. More specifically, alternate and/or direct current electrolysis is preferably carried out in an electrolyte having hydrochloric acid or nitric acid content of 0.1 to 50% by mass at a temperature of from 20 to 80° C. and an electric current density of 100 to 400 C/dm² for 1 second to 30 minutes.

The aluminum support thus surface-roughened may be chemically etched in an acid or alkaline solution. Preferable examples of the etching agent include sodium hydroxide, sodium carbonate, sodium aluminate, sodium metasilicate, sodium phosphate, potassium hydroxide, and lithium hydroxide. The concentration of the etching agent is preferably from 1 to 50% by mass, and the temperature of the etching agent is preferably from 20 to 100° C. In order to remove stains (smuts) that remain on the etched surface, the substrate may be washed with acid. Typical examples of the acid to be used include nitric acid, sulfuric acid, phosphoric acid, chromic acid, hydrofluoric acid, and fluoroboric acid. A method for removing smuts on an electrochemically roughened surface is preferably a method described in JP-A No. 53-12739 in which a surface is brought into contact with 15 to 65% by mass of sulfuric acid at a temperature in the range of from 50 to 90° C., or a method described in JP-B 48-28123 in which a surface is etched with alkali. The method and conditions are not particularly limited, as long as the surface roughness Ra of the roughened surface is about 0.2 μm to 0.5 μm after the treatment.

[Anodizing Treatment]

The aluminum support thus treated, on which an oxide layer is formed, may be subjected to an anodizing treatment.

In the anodizing treatment, an aqueous solution of any one of sulfuric acid, phosphoric acid, oxalic acid, boric acid, or sodium borate may be used alone as the major component in an electrolytic bath, or an aqueous solution of a combination of two or more of such substances may be used. In this case, the electrolytic solution may, of course, include at least components normally included in the Al alloy plate, the electrodes, tap water and underground water. A second component, or second and third components may also be included. Examples of the second component or second and third components described above include: cations of metals such as Na, K, Mg, Li, Ca, Ti, Al, V, Cr, Mn, Fe, Co, Ni, Cu or Zn, and ammonium ions; and anions such as a nitrate ion, a carbonate ion, a chlorine ion, a phosphate ion, a fluorine ion, a sulfite ion, a titanate ion, a silicate ion or a borate ion. The concentration of the cation or the anion in the electrolytic solution may be from about 0 to 10000 ppm. Although the conditions for the anodizing treatment are not particularly limited, the plate is preferably treated in 30 to 500 g/litter at a temperature of 10 to 70° C. by direct current or alternating current electrolysis in a range of an electric current density of 0.1 to 40 A/m². The thickness of the anodized layer thus formed may be in the range of from 0.5 μm to 1.5 μm, preferably in the range of from 0.5 μm to 1.0 μm. Conditions for the anodizing treatment are preferably selected so that the resultant support has a pore diameter of micropores present in the anodized layer thereof of from 5 to 10 nm and a pore density thereof of from 8×10¹⁵ to 2×10¹⁶ per square meter.

The treatment for imparting hydrophilicity to the surface of the support may be selected from various known methods. The treatment is particularly preferably hydrophilicity-imparting treatment with a silicate, polyvinylphosphonic acid, or the like. The resultant layer may have a Si or P element content of from 2 to 40 mg/m², preferably from 4 to 30 mg/m². The coating amount can be measured by fluorescence X ray analysis.

In the hydrophilicity-imparting treatment, the aluminum support having an anodized layer formed thereon is dipped in an aqueous solution at pH 10 to 13 (determined at 25° C.) including an alkali metal silicate or polyvinylphosphonic acid in an amount of from 1 to 30 mass %, and more preferably from 2 to 15 mass %, for example at from 15 to 80° C. for from 0.5 to 120 seconds.

Examples of the alkali metal silicate used in the hydrophilicity-imparting treatment include sodium silicate, potassium silicate, and lithium silicate. Examples of a hydroxide used to increase the pH of the aqueous solution of the alkali metal silicate include sodium hydroxide, potassium hydroxide, and lithium hydroxide. An alkaline earth metal salt or a salt of a metal in the group IVB may be incorporated into the treating solution. Examples of the alkaline earth metal salt include nitrates such as calcium nitrate, strontium nitrate, magnesium nitrate, and barium nitrate, sulfates, hydrochlorides, phosphates, acetates, oxalates, borates, and other water-soluble salts. Examples of the salt of a metal in the group IVB include titanium tetrachloride, titanium trichloride, titanium potassium fluoride, titanium potassium oxalate, titanium sulfate, titanium tetraiodide, zirconium chlorooxide, zirconium dioxide, zirconium oxychloride, and zirconium tetrachloride.

One of the alkaline earth metal salts or the salts of a metal in the group IVB may be used alone, or two or more thereof may be used in combination. The amount of the metal salt(s) in the treating solution is preferably from 0.01 to 10% by mass, more preferably from 0.05 to 5.0% by mass. Also, it is effective to use silicate electrodeposition as described in U.S. Pat. No. 3,658,662. Furthermore, it is preferable to subject a support which has been subjected to electrolytic graining, as disclosed in JP-B No. 46-27481, and JP-A Nos. 52-58602 and 52-30503, to a surface treatment that is a combination of the anodizing treatment with the hydrophilicity-imparting treatment.

<Photosensitive Layer>

A photosensitive layer in a negative-working photosensitive material of the invention contains (A) an infrared absorbent, (B) an organic boron compound, (C) an onium salt compound and (D) a compound having a polymerizable unsaturated group, and preferably further contains (E) a binder resin. In the negative-working photosensitive layer like this, an infrared absorbent (A) in an exposure region generates heat by exposure, (C) an organic boron compound or (C) an onium salt compound generates radicals owing to the heat, and, with the radicals as an initiation species, a compound having (D) a polymerizable unsaturated group is polymerized and cured.

[(A) Infrared Absorbent]

An infrared absorbent available in the invention is not particularly restricted as long as it has an absorption in a wavelength region from visible light to infrared light and photo-thermal conversion capability. However, a dye or pigment having the absorption maximum in a wavelength from 760 to 1200 nm is preferred.

The infrared absorbent works as a sensitizer that sensitizes a radical generator described later and has a function of converting absorbed infrared ray into heat and a function of generating excited electrons. When the infrared absorbent absorbs light, the radical generator is decomposed to generate a radical.

As the infrared-absorbing pigments available in the ink of the invention, commercially available pigments and pigments described in Color Index (edited by The Society of Dyers and Colourists), Saisin Ganryo Binran (Revised New Handbook of Pigments), edited by Nippon Ganryo Gijutsu Kyokai (Japan Pigment Technical Society) (1977), Saishin Ganryo Oyo Gijutsu (Latest Pigment Application Technology), (CMC Shuppan, 1986), Insatsu Ink Gijutsu (Print Ink Technology), (CMC Shuppan, 1984). Examples of kinds of pigment include a black pigment, a yellow pigment, an orange pigment, a brown pigment, a red pigment, a violet pigment, a blue pigment, a green pigment, a fluorescent pigment, and a polymer bonded dye. Specifically, examples thereof include, for example, an insoluble azo pigment, an azo lake pigment, a condensed azo pigment, a chelate azo pigment, a phthalocyanine pigment, an anthraquinone pigment, a perylene pigment, a perynone pigment, a thioindigo pigment, a quinacridone pigment, a dioxazine pigment, an isoindolinone pigment, a quinophthalone pigment, a dying lake pigment, an azine pigment, a nitroso pigment, a nitro pigment, a natural pigment, a fluorescent pigment, an inorganic pigment and carbon black.

The pigments may be either the above-mentioned bare pigments or surface-treated pigments. As surface treatment methods, a method of coating a surface of the pigment with a resin or wax, a method of bonding a surfactant to the pigment, and a method of bonding a reactive substance such as a silane coupling agent, an epoxy compound or a polyisocyanate to a surface of the pigment are cited. The surface treatment methods are described in “Kinzoku Sekken no Seishitsu to Oyo (Properties and Application of Metal Soaps)” (Saiwai Shobo), “Saishin Ganryo Oyo Gijutsu (Latest Pigment Application Technology)” (CMC Shuppan, 1986) and “Insatsu Ink Gijutsu (Print Ink Technology)”, (CMC Shuppan, 1984). A particle diameter of the pigment used in the invention is preferably in the range of 0.01 to 15 μm and more preferably in the range of 0.01 to 5 μm.

As the infrared absorbing dye used in the invention, well-known dyes may be used without restriction. Examples thereof include commercially available infrared absorbents and infrared absorbents described in, for example, “Senryo Binran” (edited by Yukigosei Kagaku Kyokai, 1970), “Shikizai-Kogaku Handbook” (edited by Shikizai-kyokai, Asakura Shoten, 1989), “Kogyoyo Shikiso no Gijutsu to Ichiba” (CMC, 1983) and “Kagaku Binran Oyo Kagaku-hen” (edited by The Chemical Society of Japan, Maruzen Shoten, 1986).

More specific examples thereof include an azo dye, a metal chain salt azo dye, a pyrazolone azo dye, an anthraquinone dye, a phthalocyanine dye, a carbonium dye, a quinone imine dye, a methine dye, a cyanine dye, an indigo dye, a quinoline dye, a nitro dye, a xanthene dye, a thiazine dye, an azine dye and an oxazine dye.

As dyes efficiently absorbing near infrared ray or infrared ray, for example, a cyanine dye, a methine dye, a naphthoquinone dye, a squarylium pigment, an aryl benzo(thio)pyridinium salt, a trimethine thiapyrylium salt, a pyrylium compound, a pentamethine thiopyrylium salt and an infrared absorbent are cited.

Among the dyes, as an infrared absorbent available in the invention, an infrared absorbing dye represented by the following formula (1) is preferred from the viewpoint of acting on (B) an organoboron compound described below to promote generation of an initiating species and thereby being capable of efficiently exerting a polymerization function.

D⁺A⁻ Formula (1)

In the formula (1), D⁺ represents a cationic dye having a color developing atomic group having an absorption in a near infrared region and A⁻ represents a counter anion.

Examples of the cationic dye having an absorption in a near infrared region include cations having a dye skeleton such as a cyanine dye, a triarylmethane dye, an aminium dye and a diimmonium dye, which have absorption in an near-infrared region. As specific examples of the dye cation like this, the followings are cited.

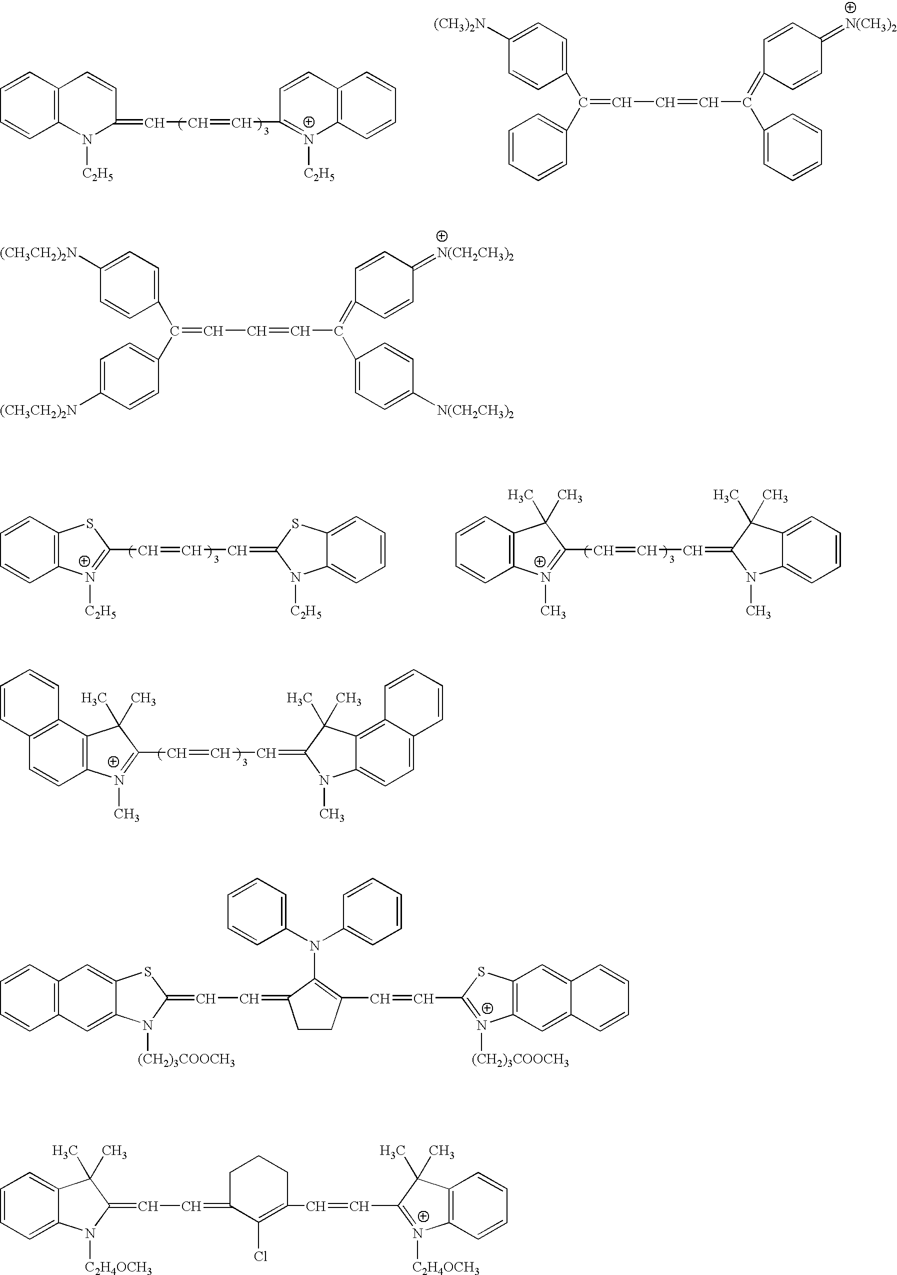

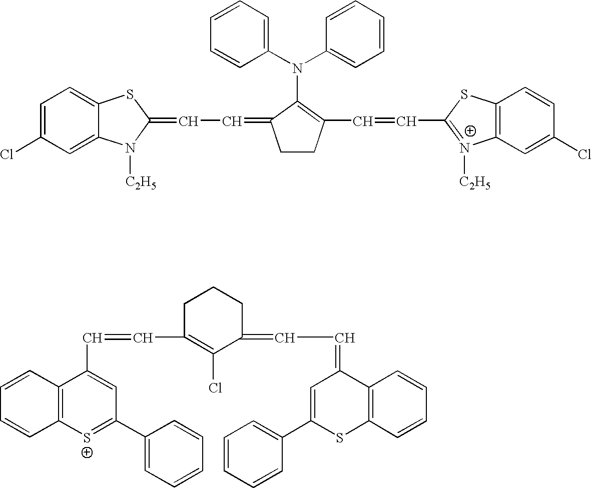

Examples of the counter anion of the dye cation represented by A⁻ include a halogen anion such as Cl⁻ or Br⁻, ClO₄⁻, PF₆⁻, BF₄⁻, SbF₆⁻, CH₃SO₃⁻, CF₃SO₃⁻, C₆H₅SO₃⁻, CH₃C₆H₄SO₃⁻, HOC₆H₄SO₃⁻, ClC₆H₄SO₃⁻ and boron anions represented by the following formula (3).

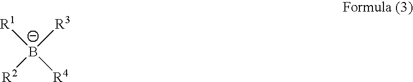

(In the formula (3), R¹, R², R³ and R⁴ each independently represents an alkyl group, an aryl group, an alkaryl group, an allyl group, an aralkyl group, an alkenyl group, an alkynyl group, an alicyclic group or a saturated or unsaturated heterocyclic group, at least one of R¹, R², R³ and R⁴ being an alkyl group having 1 to 8 carbon atoms.

As the boron anion represented by the formula (3), triphenyl n-butyl boron anion and trinaphthyl n-butyl boron anion are preferred.

Among these, as a cation dye having absorption in a near infrared region, those represented a formula (4) below are preferred.

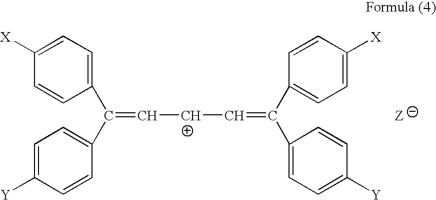

In the formula (4), Xs may be same with or different from each other and represent N(C₂H₅)₂ or N(CH₃)₂, Ys may be same with or different from each other and represent N(C₂H₅)₂, H, or OCH₃, and Z⁻ represents a counter anion selected from the following formulas.

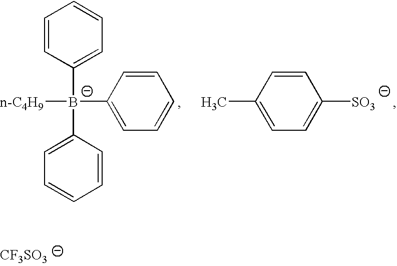

Since such infrared absorbents all have a maximum absorption wavelength in the range from 817 to 822 nm, a resulting lithographic printing plate precursor is suitable for exposure with an exposure apparatus equipped with an existing near infrared semiconductor laser. As the molar absorption coefficient thereof is 1×10⁵ or more, a photosensitive lithographic printing plate precursor containing such an infrared absorbent is capable of recording with an infrared laser at high sensitivity.

As (A) an infrared absorbent, at least one capable of absorbing a specified wavelength of an exposure light source used to expose may be selected from the pigments or dyes and used. The infrared absorbents may be used singularly or in a combination of at least two kinds thereof.

In the case of using a pigment as (A) the infrared absorbent in a photosensitive layer involving the invention, a content of the pigment is preferably in the range from 0.5 to 15% by mass, and particularly preferably from 1 to 10% by mass, based on a total solid content of a composition constituting a negative-working photosensitive layer. When the content of the pigment is within the range, sufficient infrared absorptivity is developed, a heat amount appropriate for recording is obtained and there is no concern of adversely affecting on the uniformity of the photosensitive layer.

In the case of using a dye as (A) the infrared absorbent, a content of the dye is preferably in the range from 0.5 to 15% by mass and particularly preferably from 1 to 10% by mass, based on a total solid content of the composition constituting the negative-working photosensitive layer. When the content of the dye is within the range, sufficient infrared absorptivity is exerted and an efficient photo-thermal conversion reaction sufficient for image formation may be obtained.

[(B) Organoboron Compound]

(B) an organoboron compound contained in a photosensitive layer of the invention develops a function as a polymerization initiator when it is used together with (A) the infrared absorbent. The organoboron compound is preferably an ammonium salt of a quaternary boron anion represented by the following formula (2).

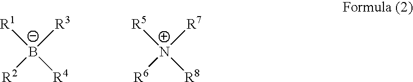

In the formula (2), R¹, R², R³ and R⁴ each independently represent an alkyl group, an aryl group, an alkaryl group, an allyl group, an aralkyl group, an alkenyl group, an alkynyl group, an alicyclic group, or a saturated of unsaturated heterocyclic group, at least one of R¹, R², R³ and R⁴ being an alkyl group having 1 to 8 carbon atoms.

R⁵, R⁶, R⁷ and R⁸ each independently represent a hydrogen atom, an alkyl group, an aryl group, an allyl group, an alkaryl group, an aralkyl group, an alkenyl group, an alkynyl group, an alicyclic group, or a saturated or unsaturated heterocyclic group.

As R¹, R², R³ and R⁴, an aryl group and an alkyl group are preferred and an aryl group is more preferred. Among the R¹, R², R³ and R⁴, at least one is an alkyl group having 1 to 8 carbon atoms. As the alkyl group, an n-butyl group and an n-octyl group are preferred and an n-butyl group is more preferred among these.

As the R⁵, R⁶, R⁷ and R⁸, an alkyl group and an aryl group are preferred and an alkyl group is more preferred.

As (B) the organoboron compound used in the invention, the following compounds are preferably cited from the viewpoint of being capable of efficiently exerting a polymerization function. Specifically, tetra n-butylammonium n-butyltriphenyl borate, tetra n-butylammonium n-butyltrinaphthyl borate, tetra n-butylammonium n-butyltri(p-t-butylphenyl)borate, tetramethylammonium n-butyltriphenyl borate, tetramethylammonium n-butyltrinaphthyl borate, tetramethylammonium n-octyltriphenyl borate, tetramethylammonium n-octyltrinaphthyl borate, tetraethylammonium n-butyltriphenyl borate, tetraethylammonium n-butyltrinaphthyl borate, trimethylhydrogen ammonium n-butyltriphenyl borate, triethylhydrogen ammonium n-butyltriphenyl borate, tetrahydrogen ammonium n-butyltriphenyl borate, tetramethylammonium tetra n-butyl boron and tetraethylammonium tetra n-butyl borate are preferably cited and, among these, tetra n-butylammonium n-butyltrinaphtyl borate is more preferred.

(B) the organoboron compound available in the invention, when used together with (A) the infrared absorbent, preferably, with an infrared absorbing dye represented by a formula (1), generates a radical (R.) by irradiation with infrared ray and develops a function as a polymerization initiator. A mechanism when (B) the organoboron compound [compound represented by a formula (2-1) shown below] reacts with an infrared absorbing dye represented by a formula (1) shown below to generate a radical (R.) is shown below.

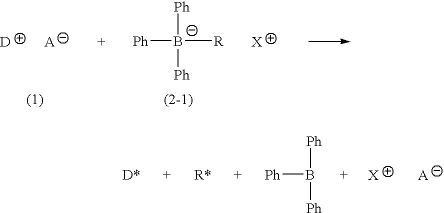

In the scheme, Ph represents a phenyl group, R represents an alkyl group having 1 to 8 carbon atoms, and X⁺ represents an ammonium ion. Others are same as in the formula (1).

In the photosensitive layer, (B) the organoboron compound may be used singularly or in a combination of at least two kinds thereof as required.

The content of (B) the organoboron compound is preferably in the range of 1 to 15% by mass, and particularly preferably in the range of 3 to 10% by mass, based on the total solid content of the composition constituting the negative-working photosensitive layer. When the content is in the above range, a polymerization reaction sufficiently proceeds with good efficiency, whereby excellent curability of an image area is achieved. Furthermore, at least two kinds of the organoboron compounds (B) may be used as required.

Still furthermore, as long as the advantages of the invention are not disturbed, in addition to (B) the organoboron compound, other known radical polymerization initiators such as triazines, hexaarylbisimidazole, a titanocene compound, a ketoxime compound, a thio compound, organic peroxide or oxime esters may be used together therewith. When these are used together, the other radical polymerization initiator is preferably added in an amount of 50 parts by mass or less with respect to 100 parts by mass of (B) the organoboron compound.

[(C) Onium Salt Compound]

(C) an onium salt compound is contained in the photosensitive layer of the invention. (C) the onium salt compound available in the invention is a salt made of a cation having at least one onium ion atom in the molecule and an anion.

Examples of the onium ion atom in (C) the onium salt include S⁺ in sulfonium, I⁺ in iodonium, N⁺ in ammonium, and P⁺ in phosphonium (excluding a diazonium compound such as a diazo resin). Among these onium ion atoms, S⁺ and I⁺ are preferred.

Examples of the anion constituting the onium salt include halogen anion, ClO₄⁻, PF₆⁻, BF₄⁻, SbF₆⁻, CH₃SO₃⁻, CF₃SO₃⁻, C₆H₅SO₃⁻, CH₃C₆H₄SO₃⁻, HOC₆H₄SO₃⁻, ClC₆H₄SO₃⁻ and boron anions represented by the formula (3).

In view of the sensitivity and storage stability, as the onium salt (C), a sulfonium salt compound and an iodonium salt compound are preferred, and a combination thereof is more preferred.

Furthermore, as the onium salt (C), a polyvalent onium salt having at least two onium ion atoms in a molecule is preferred from the viewpoint of the sensitivity and storage stability. At least two onium ion atoms in the cation are bonded through a covalent bond. Among polyvalent onium salts, those having at least two different of onium ion atoms in one molecule are preferable and those having S⁺ and I⁺ in a molecule are particularly preferable. In particular, as the polyvalent onium salts, compounds represented by the following formula (6) and compounds represented by the following formula (7) are preferably cited.

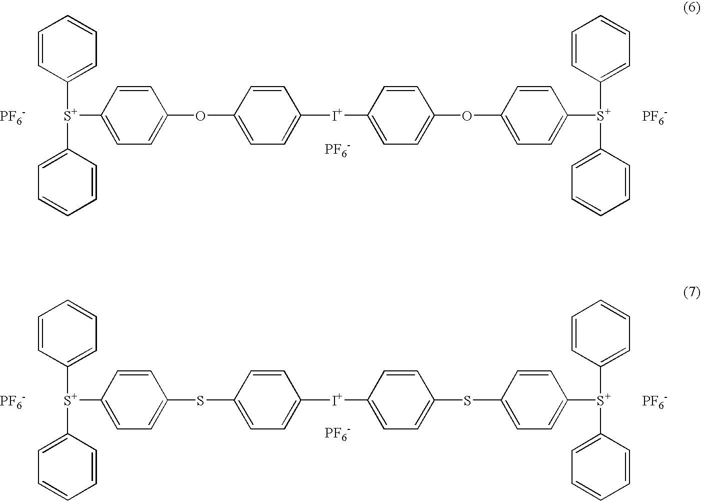

The onium salt (C) used in the invention is preferably a compound having an aromatic ring having a substituent group from the viewpoint of the sensitivity, developability and printing durability. Examples of substituent group preferably include C₁ to C₆ alkyl groups such as a methyl group, an ethyl group, a propyl group, an isopropyl group, a butyl group, an isobutyl group, a sec-butyl group, a tert-butyl group, a pentyl group, an isopentyl group, a neopentyl group, a tert-pentyl group, a hexyl group and an isohexyl group, and particularly preferably a methyl group, a sec-butyl group, a tert-butyl group, and a tert-pentyl group. Examples of aromatic ring include a benzene ring and a naphthalene ring, a benzene ring being more preferred.

In particular, the onium salt (C) preferably has at least two aromatic rings having a substituent group and those having a skeleton such as diaryliodonium salt or a triarylsulfonium salt are preferred. Substituent groups that an aromatic ring in a skeleton like this has may be same with or different from each other in the at least two aromatic rings. However, the substituent groups are preferred to be different from the viewpoint of the solubility.

The onium salts (C) may be used singularly or in a combination of at least two different of the onium salts (C) as required. Furthermore, a polyvalent onium salt and a monovalent onium salt may be used together. In the case where at least two different of monovalent onium salts are used together, it is preferred to use a sulfonium salt and an iodonium salt together as mentioned above.

A content of the onium salt (C) is preferably in the range of 2 to 30% by mass and particularly preferably in the range of 5 to 20% by mass, based on a total solid content of the composition constituting the negative-working photosensitive layer. When the onium salt (C) is contained within the range, a sufficient polymerization reaction is obtained, and the sensitivity when the photosensitive layer is formed, the printing durability in an image area and developability in a non-image area all become excellent.

[(D) Compound Having Polymerizable Unsaturated Group]

(D) a compound having a polymerizable unsaturated group in the invention [hereinafter, appropriately, referred to as a polymerizable compound (D)] is a monomer or oligomer having at least one, preferably at least two addition polymerizable ethylenically unsaturated groups in one molecule and preferably has a boiling temperature under normal pressure of 100° C. or more.

Examples of such monomer or oligomer include, for example, mono-functional (meth)acrylate such as polyethylene glycol mono(meth)acrylate, polypropylene glycol mono(meth)acrylate or phenoxyethyl(meth)acrylate; polyvalent(meth)acrylate such as polyethylene glycol di(meth)acrylate, polypropylene glycol di(meth)acrylate, trimethylolpropane tri(meth)acrylate, neopentyl glycol di(meth)acrylate, pentaerythritol tri(meth)acrylate, pentaerythritol tetra(meth)acrylate, dipentaerythritol hexa(meth)acrylate, hexanediol di(meth)acrylate, tri(acryloyloxyethyl)isocyanurate, (meth)acrylate of polyhydric alcohol-alxylene oxide adduct, (meth)acrylate of polyhydric phenol-alkylene oxide adduct, urethane acrylates, polyester acrylates, and epoxy acrylates obtained by addition reaction of an epoxy resin and (meth)acrylic acid; and polyfunctional allyl compounds such as allyl isocyanurate and allyl cyanurate.

In the photosensitive layer, the polymerizable compounds (D) may be added singularly or in a combination of at least two different thereof as required.

A content of the polymerizable compound (D) is preferably in the range of 5 to 60% by mass and more preferably in the range of 20 to 50% by mass, based on a total solid content of the composition constituting the negative-working photosensitive layer. When the content of the polymerizable compound (D) is within the range, sufficient curability is obtained and the tackiness of a surface of an image area caused by a low molecular weight component as well is inhibited from occurring.

[(E) Binder Resin]

In addition to the indispensable components (A) through (D), a binder resin (E) may be contained in the photosensitive layer of the invention to improve the film property.

As the binder resin (E), known binder resins available in a negative-working planographic printing plate precursor may be used without restriction.

Examples of the binder resin like this include, for example, copolymers such as a (meth)acrylic acid-(meth)acrylic acid ester copolymer, a copolymer containing hydroxy alkyl(meth)acrylate and (meth)acrylonitrile, a copolymer having an aromatic hydroxyl group or a polymer having a 2-hydroxy-3-phenoxypropyl (meth)acrylate unit; an epoxy resin; a polyamide resin; halogenated vinyl such as polyvinyl chloride or polyvinylidene chloride; polyvinyl acetate; polyester; an acetal resin such as a formal resin or a butyral resin; a soluble polyurethane resin available from Goodrich Corporation, USA, under a trade name of ESTAN; polystyrene; styrene-maleic anhydride copolymer or half ester thereof, a cellulose derivative; shellac; a rosin or modified compound thereof, and a copolymer having an unsaturated group in the side chain.

The binder resin (E) is preferably an alkali-soluble resin because it is capable of developing with a developing solution of an aqueous alkali solution. The alkali-soluble resin refers to a binder resin insoluble in water and soluble in an aqueous alkali solution, and is specifically a resin having an alkali-soluble group such as a carboxyl group, a phenolic hydroxyl group, a sulfonic acid group, a phosphone group, an active imino group or a N-sulfonylamide group.

Examples of the alkali-soluble resin include, for example, novolak resin or resol resin such as phenol-formaldehyde resin, cresol-formaldehyde resin or phenol-cresol-formaldehyde cocondensed resin; polyhydroxystyrene such as polyhydroxystyrene or polyhalogenated hydroxystyrene; acrylic resin having at least one unit derived from a monomer having an acidic group, such as N-(4-hydroxyphenyl)methacrylamide, hydroquinone monomethacrylate, N-(sulfamoylphenyl)methacrylamide, N-phenylsulfonylmethacrylamide, N-phenylsulfonylmaleimide, acrylic acid, methacrylic acid, N-(4-carboxyphenyl)methacrylamide, 4-carboxystyrene or mono(2-methacryloxyethyl) hexahydrophthalate; vinyl-based resin having an active methylene group or a urea bond; polyurethane resin such as polyurethane resin having an N-sulfonylamide group, an N-sulfonylureide group or an N-aminosulfonylamide group, polyurethane resin having an active imino group, or polyurethane resin having a carboxyl group; polyamide resins such as polyhydroxypolyamide; and polyester resin having a phenolic hydroxyl group.

As the binder resin (E), a binder resin having a polymerizable unsaturated group such as an acryloyl group, a methacryloyl group or an allyl group in the side chain is preferably used. Since such a binder resin forms a crosslinking structure with a polymerizable compound (C), crosslinking density is improved and the printing durability of the photosensitive planographic printing plate is effectively improved.

Furthermore, as the binder resin (E), a polymer having an aromatic carboxyl group as well is preferred from the viewpoint of an improvement in the printing durability. A polymer or copolymer containing a structural unit having such a functional group as a side chain structure is particularly preferred.

The aromatic carboxyl group herein is an aromatic group having a carboxyl moiety such as —C₆H₅COOH. The aromatic carboxyl group exists preferably in the side chain of a (co)polymer. Such a side chain structure may be directly bonded to a main chain of the (co)polymer or bonded via an appropriate linkage group. Examples of the linkage group that links a main chain structure of the binder resin and an aromatic carboxyl group includes, for example, a divalent group such as an alkylene group, —CO—, —COO—, —CONH—, —NH—, —NHCONH— and a divalent linkage group formed by bonding at least two thereof.

The main chain and the aromatic carboxyl group are preferably bonded via a linkage group and it is preferred that the linkage group exists between a carbon atom of a main chain and a carbon atom of the aromatic hydroxyl group and has a distance of 8 to 10 atoms used in the linkage group.

A weight average molecular weight of the binder resin (E) in the invention is appropriately determined from the viewpoint of the image forming property and printing durability and preferably in the range of 10,000 to 300,000 and more preferably in the range of 30,000 to 100,000.

When the binder resin (E) is used in the photosensitive layer, only one kind thereof may be used or a plurality of different thereof may be used as required.

A content of the binder resin (E) is preferably in the range of 20 to 70% by mass based on the solid content of the composition of the negative-working photosensitive layer. That is, the binder resin is not necessarily required. However, when the binder resin (E) is added to obtain a sufficient advantage such as an improvement in film quality, the binder resin (E) is preferably added 20% or more by mass, and within the range a sufficient improvement in the curability of the photosensitive layer and in the film strength may be obtained.

<Negative-Working Photosensitive Layer>

To the photosensitive layer of the negative-working photosensitive material of the invention, in addition to the component (A) through component (D) and the component (E) that is preferably used together therewith, known additives such as colorants (dyes, pigment), surfactants, plasticizers, stability modifiers and polymerization inhibitors may be added, as required, as long as the additive does not disturb advantages of the invention.

A dye is added to improve the plate inspection property. Examples of dyes preferably available in the invention include, for example, basic oil-soluble dyes such as Crystal Violet, Malachite Green, Victoria Blue, Methylene Blue, Ethyl Violet and Rhodamine B. Examples of the commercially available dyes include, for example, “Victoria Pure Blue BOH” (trade name, manufactured by HODOGAYA CHEMICAL Co., Ltd.), “Oil Blue #603” (trade name, manufactured by Orient Chemical Industries, LTD.), “VPB-Naps (naphthalene sulfonate of Victoria Pure Blue)” (trade name, manufactured by HODOGAYA CHEMICAL Co., Ltd.) and “D11” (trade name, manufactured by PCAS Co.). Examples of the pigments include, for example, Phthalocyanine Blue, Phthalocyanine Green, Dioxadine Violet and Quinacridone Red.

The coating property and coated surface property of the photosensitive layer are improved when a surfactant is added. Examples of the surfactants include all of an anionic surfactant, a cationic surfactant, an amphoteric surfactant and a nonionic surfactant. However, a fluorine-based surfactant and a silicone-based surfactant are preferred from the viewpoint of advantage.

Examples of the plasticizer include, for example, diethyl phthalate, dibutyl phthalate, dioctyl phthalate, tributyl phosphate, trioctyl phosphate, tricresyl phosphate, tri(2-chloroethyl) phosphate and tributyl citrate.

As the known stability improver, for example, phosphoric acid, phosphorous acid, oxalic acid, tartaric acid, malic acid, citric acid, dipicolinic acid, polyacrylic acid, benzenesulfonic acid and toluenesulfonic acid may be used in combination.

A little amount of a thermal polymerization inhibitor is desirably added in the negative-working photosensitive layer in the invention to inhibit unnecessary thermal polymerization of the polymerizable compound from occurring during production or storage of the photosensitive layer. Examples of appropriate thermal polymerization inhibitors include known phenolic compound, quinones, N-oxide compound, amine-based compound, sulfide group-containing compound, nitro group-containing compound and transition metal compound. Specific examples thereof include hydroquinone, p-methoxyphenol, p-cresol, pyrogallol, t-butylcatechol, benzoquinone, 4,4′-thiobis(3-methyl-6-t-butylphenol), 2,2′-methylenebis(4-methyl-6-t-butylphenol), 2-mercaptobenzimidazole and N-nitrosophenylhydroxyamine primary cerium salt. An addition amount of the thermal polymerization inhibitor is preferably 0.01% by mass or more and 5% by mass or less.

The contents of the various additives vary depending on the purposes, but are normally within the range of 0 to 30% by mass based on the total solid content of the composition constituting the photosensitive layer.

Furthermore, as required, a high fatty acid derivative such as stearic acid, behenic acid, behenic acid amide or methyl behenate may be added and localized on a surface of the negative-working photosensitive layer in the course of drying after coating to inhibit oxygen from disturbing the polymerization inhibition. An addition amount of the higher fatty acid derivative is preferably 0.5% by mass or more and 10% by mass or less relative to a total nonvolatile component in the negative-working photosensitive layer.

In order to improve the printing durability of the resulted negative-working photosensitive planographic printing plate, a sensitizer such as hexaarylbiimidazoles or ketocoumarines; or a cyanine-based sensitizing dye cation having a structure where heterocyclic rings are bonded through a polymethylene chain and/or phthalocyanine-based sensitizing dye may be contained in the negative-working photosensitive composition of the invention.

In the negative-working photosensitive composition such as mentioned above, the infrared absorber (A) is used in combination with (B) the organoboron compound. (B) the organoboron compound has a function as a polymerization initiator by using in combination with (A) the infrared absorbent; accordingly, the polymerization of the polymerizable compound (D) is caused and forwarded to cure an exposed portion under exposure of infrared light. Accordingly, the photosensitive layer of the negative-working photosensitive material of the invention is capable of forming an image under exposure with infrared light.

Although the reason of the action is not clear, by using (B) the organoboron compound as the polymerization initiator, polymerization inhibition caused by oxygen is less likely to occur during the radical polymerization.

Furthermore, when (C) the onium salt compound is used together, the radical polymerization initiated by using (A) the infrared absorbent in combination with (B) the organoboron compound is accelerated and the negative-working photosensitive layer is improved in the storage stability. The excellent effects in the invention are not exerted until (B) the organoboron compound and (C) the onium salt compound are used in combination, that is, the excellent effects are not exerted when (B) the organoboron compound and (C) the onium salt each are independently used as the polymerization initiator.

From what was mentioned above, it is found that when the negative-working photosensitive layer in the invention containing the component (A) through component (D) and preferably further containing the component (E) is combined with (B) the organoboron compound that causes less polymerization inhibition caused by oxygen during the radical polymerization, and (C) the onium salt that accelerates the radical polymerization and improves storage stability, high sensitivity is achieved and curability becomes excellent. Accordingly, the negative-working photosensitive layer of the invention is sufficiently curable without disposing an overcoat layer for inhibiting oxygen in air from adversely affecting and does not necessitate heating after exposure.

Accordingly, when the undercoat layer and the negative-working photosensitive layer in the invention are disposed on a support, a negative-working photosensitive material high in the sensitivity and excellent in the printing durability and storage stability is obtained and the photosensitive material is useful as a photosensitive planographic printing plate precursor.

[Preparation of Negative-Working Photosensitive Material]

The photosensitive material of the invention has the undercoat layer and photosensitive layer that have been detailed above on a support. According to the configuration, an oxygen-blocking overcoat layer is not necessary to dispose, excellent image formability is obtained, and a formed image area is excellent in the printing durability. However, a protective layer and so on may be disposed as required to inhibit the photosensitive layer from being scratched and to control the physical property at the time of contact with a back surface of the support. Such a negative-working photosensitive material is produced by sequentially coating the coating solutions containing the respective components on a support.

The negative-working photosensitive layer of the invention is disposed by dissolving (A) the infrared absorbent, (B) organoboron compound, (C) onium salt compound and (D) the compound having a polymerizable unsaturated group in various solvents, followed by coating on an undercoat layer described below.

Examples of the solvent used herein include, for example, alcohols such as methyl alcohol, ethyl alcohol, n- or iso-propyl alcohol, n- or iso-butyl alcohol or diacetone alcohol; ketones such as acetone, methyl ethyl ketone, methyl propyl ketone, methyl butyl ketone, methyl amyl ketone, methyl hexyl ketone, diethyl ketone, diisobutyl ketone, cyclohexanone, methyl cyclohexanone or acetylacetone; hydrocarbons such as hexane, cyclohexane, heptane, octane, nonane, decane, benzene, toluene, xylene or methoxybenzene; acetate esters such as ethyl acetate, n- or isopropyl acetate, n- or isobutyl acetate, ethylbutyl acetate or hexyl acetate; halides such as methylene dichloride, ethylene dichloride or monochlorobenzene; ethers such as isopropyl ether, n-butyl ether, dioxane, dimethyldioxane or tetrahydrofuran; polyhydric alcohols and derivatives thereof, such as ethylene glycol, ethylene glycol monomethyl ether, ethylene glycol monomethyl ether acetate, ethylene glycol monoethyl ether, ethylene glycol monoethyl ether acetate, ethylene glycol monobutyl ether, ethylene glycol monobutyl ether acetate, ethylene glycol dimethyl ether, ethylene glycol diethyl ether, ethylene glycol dibutyl ether, methoxyethoxy ethanol, diethylene glycol monomethyl ether, diethylene glycol dimethyl ether, diethylene glycol methylethyl ether, diethylene glycol diethyl ether, propylene glycol, propylene glycol monomethyl ether, propylene glycol monomethyl ether acetate, propylene glycol monoethyl ether, propylene glycol monoethyl ether acetate, propylene glycol monobutyl ether, 3-methyl-3-methoxybutanol or 1-methoxy-2-propanol; and special solvents such as dimethyl sulfoxide, N,N-dimethylformamide, methyl lactate or ethyl lactate. The solvents may be used singularly or in a combination thereof.

The solid content in the coating solution is preferably from 2 to 50% by mass.

Examples of the coating method of the photosensitive layer include, for example, roll coating, dip coating, air knife coating, gravure coating, gravure offset coating, hopper coating, blade coating, wire doctor coating, and spray coating methods.

The coating weight of the negative-working photosensitive composition is preferably in the range of 10 to 100 ml/m².

The photosensitive layer forming composition applied on the support is usually dried in heated air. The drying temperature (temperature of the heated air) is preferably from 30 to 200° C., and particularly preferably from 40 to 140° C. Not only a method of maintaining the drying temperature at a fixed temperature during drying, but also a method of stepwisely raising the drying temperature may be employed. Preferred results may be obtained sometimes by dehumidifying the air. The heated air is preferably blown against the coated surface at a rate from 0.1 to 30 m/second, and particularly preferably from 0.5 to 20 m/second.

The coating weight of the negative-working photosensitive layer is preferably in the range of 0.1 to 10 g/m² and more preferably in the range of 0.5 to 5 g/m² in terms of a dry mass from the viewpoint of the printing durability and sensitivity.

<Backcoat Layer>

In the negative-working photosensitive material, a back surface of the support is preferably modified to improve the scratch resistance. As a modifying method of the back surface of the support, when, for instance, an aluminum support is used, a method where an anodic oxidation film is formed uniformly over an entire surface on the back surface thereof in a manner similar to a recording layer side or a method where a backcoat layer is formed is cited.

A film formation amount when an anodic oxidation film is formed is preferably 0.6 g/m² or more and more preferably in the range of 0.7 to 6 g/m². Among these, a method of disposing a backcoat layer is more effective and preferred. As the backcoat layer, a backcoat layer that is described in paragraphs [0168] to [0175] of JP-A No. 2008-15503 and contains a metal oxide and colloidal silicasol and a backcoat layer that is described in paragraphs [0176] to [0183] of the same publication and made of an organic resin film are preferably used.

Examples of a method of coating a backcoat layer coating solution on a surface of a support include, for example, a bar coater, a roll coater, a gravure coater, and a known measuring and coating device such as a curtain coater, extruder or a slide hopper. Among these, a non-contact measuring coater such as a curtain coater, an extruder or a slide hopper is particularly preferred from the viewpoint of being free from scratch on a back surface of the support.

<Negative-Working Planographic Printing Plate Precursor>

The negative-working photosensitive material of the invention may be preferably used in a negative-working planographic printing plate precursor (hereinafter, referred to as “a planographic printing plate precursor of the invention” in some cases). When the negative-working planographic printing plate precursor of the invention is subjected to plate making by a method as shown below, a planographic printing plate excellent in the printing durability and stain resistance of a non-image area may be obtained.

[Plate-Making Method]

At least processes of exposure and development are conducted to subject the planographic printing plate precursor of the invention to plate-making process.

In what follows, a plate-making method of the planographic printing plate precursor of the invention will be described.

In the plate-making method of a planographic printing plate precursor of the invention, for instance, the planographic printing plate precursor is exposed imagewise with a wavelength from 750 to 1400 nm, followed by developing and removing a non-image area, and thereby the plate-making process comes to completion.

[Exposure]

As an exposure method of the planographic printing plate precursor of the invention, known methods that use infrared ray are used without restriction.

As a light source for exposing the planographic printing plate precursor of the invention, an infrared laser is preferably cited. As the laser light source used in the invention, a high output laser having the maximum intensity in a region from near-infrared ray to infrared ray is preferably used because a negative-working planographic printing plate precursor may be handled in a bright room. As such high output laser having the maximum intensity in a region from near-infrared ray to infrared ray, various lasers having the maximum intensity in a region from near-infrared ray to infrared ray of 760 to 1200 nm such as semiconductor lasers and YAG lasers are cited.

In the invention, solid-state lasers and semiconductor lasers emitting infrared ray having a wavelength from 750 to 1400 nm are preferably used to conduct image exposure. An output of the laser is preferred to be 100 mW or more and a multi-beam laser device is preferably used to shorten an exposure time. An exposure time per pixel is preferably 20 μsec or less. The planographic printing plate precursor is preferably exposed with the energy from 10 to 300 mJ/cm². When the exposure energy is 10 mJ/cm² or more, the negative-working photosensitive layer is sufficiently cured. When the exposure energy is 300 mJ/cm² or less, the negative-working photosensitive layer is not laser-ablated and an image is not damaged.

[Development]

A planographic printing plate on which an image area is written is obtained in such a manner that an image is written in a photosensitive layer of a negative working photosensitive planographic printing plate precursor of the invention with laser, followed by developing, further followed by removing a non-image area by wet process. In the invention, the development step may be applied immediately after the laser irradiation. However, a heating step may be disposed between a laser irradiation step and a development step. The heating step is carried out at a temperature in the range of 80 to 150° C. for 10 sec to 5 min. By the heating step, energy necessary for writing in an image during laser irradiation may be diminished.

As a developing solution used in a development step, an alkali aqueous solution of pH of 14 or less is preferred and an alkali aqueous solution of pH from 8 to 12 containing an anionic surfactant is more preferably used. Examples of inorganic alkali agent include, for example, tribasic sodium phosphate, tribasic potassium phosphate, tribasic ammonium phosphate, dibasic sodium phosphate, dibasic potassium phosphate, dibasic ammonium phosphate, sodium carbonate, potassium carbonate, ammonium carbonate, sodium hydrogen carbonate, potassium hydrogen carbonate, ammonium hydrogen carbonate, sodium borate, potassium borate, ammonium borate, sodium hydroxide, ammonium hydroxide, potassium hydroxide and lithium hydroxide. Examples of organic alkali agent include, for example, monomethylamine, dimethylamine, triethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine and pyridine. These alkali agents may be used singularly or in a combination of at least two different thereof.

In the development step of the planographic printing plate precursor of the invention, an anionic surfactant is added from 1 to 20% by mass and more preferably from 3 to 10% by mass in the developing solution. When an addition amount is too small, the developability is deteriorated and when an addition amount is too much the strength such as the friction resistance is deteriorated.

Examples of anionic surfactant include, for example, sodium lauryl alcohol sulfate, ammonium lauryl alcohol sulfate and sodium octyl alcohol sulfate; alkyl aryl sulfonates such as sodium isopropyl naphthalene sulfonate, sodium isobutyl naphthalene sulfonate, sodium salt of polyoxyethylene glycol mononaphthyl ether sulfonic acid ester, sodium dodecyl benzene sulfonate and sodium methanitro benzene sulfonate; sulfuric esters of higher alcohol having 8 to 22 carbon atoms such disodium alkyl sulfate; aliphatic alcohol phosphoric ester salts such as sodium cetyl alcohol phosphate; alkyl amide sulfonate salts such as C₁₇H₃₃CON(CH₃)CH₂CH₂SO₃Na; sulfonate of dibasic aliphatic ester such as dioctyl sodium sulfosuccinate and dihexyl sodium sulfosuccinate.

Also, an organic solvent capable of being mixed with water, such as benzyl alcohol, may be added to the developing solution, as required. As the organic solvent, those having the solubility in water of not more than substantially 10% by mass, and preferably not more than 5% by mass are selected. Examples thereof include, for example, 1-phenylethanol, 2-phenylethanol, 3-phenylpropanol, 1,4-phenylbutanol, 2,2-phenylbutanol, 1,2-phenoxyethanol, 2-benzyloxyethanol, o-methoxybenzyl alcohol, m-methoxybenzyl alcohol, p-methoxybenzyl alcohol, benzyl alcohol, cyclohexanol, 2-methylcyclohexanol, 4-methylcyclohexanol, and 3-methylcyclohexanol. A content of the organic solvent is suitably from 1 to 5% by mass based on the total mass of the developing solution at the time of use. Its use amount is closely related to the amount of the surfactant used, and it is preferred to increase the amount of the anionic surfactant with an increase in the organic solvent. This is because when the amount of the organic solvent is increased in the state where the amount of the anionic surfactant is small, the organic solvent does not dissolve; accordingly, excellent developability is not expected.

Furthermore, additives such as a defoaming agent and a hard water softener may be further contained in the developing solution, as required. Examples of hard water softeners include, for example, polyphosphate such as Na₂P₂O₇, Na₅P₃O₃, Na₃P₃O₉, Na₂O₄P (NaO₃P)PO₃Na₂, and Calgon (polysodium metaphosphate); amino polycarboxylic acids (such as ethylenediaminetetraacetic acid and its potassium salt and sodium salt; diethylenetriaminepentaacetic acid and its potassium salt and sodium salt; triethylenetetraminehexaacetic acid and its potassium salt and sodium salt; hydroxyethyl ethylenediaminetriacetic acid and its potassium salt and sodium salt; nitrilotriacetic acid and its potassium salt and sodium salt; 1,2-diaminocyclohexanetetraacetic acid and its potassium salt and sodium salt; or 1,3-diamino-2-propanoltetraacetic acid and its potassium salt and sodium salt); other polycarboxylic acids (such as 2-phosphonobuthane tricarboxylic acid-1,2,4 and its potassium salt and sodium salt; and 2-phosphonobuthane tricarboxylic acid-2,3,4 and its potassium salt and sodium salt); organic phosphonic acids (such as 1-phosphonoetanetricarboxylic acid-1,2,2 and its potassium salt and sodium salt; 1-hydroxyethane-1,1-diphosphonic acid, and its potassium salt and sodium salt; and aminotrimethylene phosphonic acid and its potassium salt and sodium salt). The optimum amount of the hard water softener varies depending upon the hardness of hard water used and its use amount, but the hard water softener is generally used in an amount in the range of 0.01 to 5% by mass, and preferably in the range of 0.01 to 0.5% by mass in the developing solution at the time of use.

Furthermore, in the case where the lithographic printing plate precursor is developed with an automatic processor, since the developing solution is exhausted depending on the treatment amount, treatment ability may be recovered with a replenisher or a fresh developing solution. In this case, it is preferable to carry out the replenishment by the method described in U.S. Pat. No. 4,882,246. Also, developing solutions described in JP-A Nos. 50-26601 and 58-54341 and JP-B Nos. 56-39464, 56-42860 and 57-7427 are preferable.

The lithographic printing plate precursor thus developed may be subjected to post treatment with, for example, washing water, a rinse solution containing a surfactant and a desensitizing solution containing gum arabic or starch derivatives as described in JP-A Nos. 54-8002, 55-115045, and 59-58431. In the post treatment of the lithographic printing plate precursor of the invention, these treatments may be employed through a variety of combinations.

The planographic printing plate precursor of the invention is excellent in the curability of the photosensitive layer and does not necessitate post-heat treatment in particular, as mentioned above. However, in plate making of the lithographic printing plate precursor of the invention, for the purpose of enhancing the image strength and printing durability, it is effective to apply entire post heating or entire exposure to an image after the development.

A very strong condition may be applied in the heating after the development. In general, the heat treatment is carried out at a temperature in the range of 200 to 500° C. from the viewpoint of being capable of obtaining sufficient image-reinforcing action and of inhibiting damage caused by heat in the support or image area from occurring.

A light source for the post-exposure is not particularly restricted. Examples thereof include, for example, carbon arc, a high-pressure mercury lamp, an ultrahigh-pressure mercury lamp, a low-pressure mercury lamp, a deep UV lamp, a xenon lamp, a metal halide lamp, a fluorescent lamp, a tungsten lamp, a halogen lamp and an excimer laser lamp. Among these, a mercury lamp and a metal halide lamp are preferred and a mercury lamp is particularly preferred.

The planographic printing plate obtained according to the treatments mentioned above is mounted on an offset printer and used to print many printed matters.

Stain of the planographic printing plate used to print may be removed with a plate cleaner. As the plate cleaner used to remove stains on the plate during printing, so far known plate cleaner for PS plate such as CL-1, CL-2, CP, CN-4, CN, CG-1, PC-1, SR and IC (trade name, manufactured by Fuji Photo-Film Co., Ltd.) are cited.

### EXAMPLES

In what follows, the invention will be described with reference to examples. However, the invention is not restricted to the examples. In the examples, “%” means “% by mass” unless clearly stated.

### (Measurement of Average Molecular Weight by Gel Permeation Chromatography (GPC))

The weight-average molecular weight of a polymer was measured by the following method, with PEG (manufactured by Tosoh Corporation) as a reference sample.

### Column: Shodex Ohpak SB-806M HQ 8×300 mm

Shodex Ohpak SB-806M HQ 8×300 mm

Shodex Ohpak SB-802.5 HQ 8×300 mm

Mobile phase: Solution of 50 mM disodium hydrogen phosphate (acetonitrile/water=1/9)
Flow rate: 0.8 ml/min

### Detector: RI

Charge amount: 100 μl
Sample concentration: 0.1% by mass

(Shodex: registered trade mark, manufactured by Showa Denko K. K.)

### Synthesis Example 1

### Synthesis of Specified Polymer

### Exemplified Compound: (a-1)

To a 200-ml three-necked flask, 11.01 g of MFG (=propylene glycol monomethyl ether) was added, followed by heating and agitating at 80° C. for 30 minutes under nitrogen (N₂) flow (80 ml/min). With the nitrogen flow rate and the temperature were maintained, a solution obtained by dissolving 3.87 g of methacrylic acid, 10.51 g of methyl methacrylate, and 0.76 g of dimethyl 2,2′-azobis(isobutyrate) in 44.04 g of MFG was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 90° C. and agitating for 2 hours, whereby 70.8 g of a target polymer (Exemplified Compound: (a-1)) was obtained (solid content: 21.94%).

### Synthesis Example 2

### Synthesis of Specified Polymer

### Exemplified Compound: (a-2)

To a 200-ml three-necked flask, 10.86 g of MFG was added, followed by heating and agitating at 80° C. for 30 minutes under nitrogen flow (80 ml/min). While the nitrogen flow rate and the temperature were maintained, a solution obtained by dissolving 5.17 g of methacrylic acid, 9.01 g of methyl methacrylate, and 0.76 g of dimethyl 2,2′-azobis(isobutyrate) in 43.44 g of MFG was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 90° C. and by agitating for 2 hours, whereby 67.1 g of a target polymer (Exemplified Compound: (a-2)) was obtained (solid content: 22.82%).

### Synthesis Example 3

### Synthesis of Specified Polymer

### Exemplified Compound: (a-3)

To a 200-ml three-necked flask, 10.71 g of MFG was added, followed by heating and agitating at 80° C. for 30 minutes under nitrogen flow (80 ml/min). While the nitrogen flow rate and the temperature were maintained, a solution obtained by dissolving 6.46 g of methacrylic acid, 7.51 g of methyl methacrylate, and 0.76 g of dimethyl 2,2′-azobis(isobutyrate) in 42.84 g of MFG was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 90° C. and by agitating for 2 hours, whereby 65.8 g of a target polymer (Exemplified Compound: (a-3)) was obtained (solid content: 22.98%).

### Synthesis Example 4

### Synthesis of Specified Polymer

### Exemplified Compound: (a-4)

To a 200-ml three-necked flask, 10.56 g of MFG was added, followed by heating and agitating at 80° C. for 30 minutes under nitrogen flow (80 ml/min). While the nitrogen flow rate and the temperature were maintained, a solution obtained by dissolving 7.75 g of methacrylic acid, 6.01 g of methyl methacrylate, and 0.76 g of dimethyl 2,2′-azobis(isobutyrate) in 42.25 g of MFG was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 90° C. and by agitating for 2 hours, whereby 62.4 g of a target polymer (Exemplified Compound: (a-4)) was obtained (solid content: 24.19%).

### Synthesis Example 5

### Synthesis of Specified Polymer

### Exemplified Compound: (a-5)

To a 200-ml three-necked flask, 10.41 g of MFG was added, followed by heating and agitating at 80° C. for 30 minutes under nitrogen flow (80 ml/min). While the nitrogen flow rate and the temperature were maintained, a solution obtained by dissolving 9.04 g of methacrylic acid, 4.51 g of methyl methacrylate, and 0.76 g of dimethyl 2,2′-azobis(isobutyrate) in 41.65 g of MFG was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 90° C. and by agitating for 2 hours, whereby 62.4 g of a target polymer (Exemplified Compound: (a-5)) was obtained (solid content: 23.52%).

### Synthesis Example 6

### Synthesis of Specified Polymer

### Exemplified Compound: (a-6)

To a 200-ml three-necked flask, 10.26 g of MFG was added, followed by heating and agitating at 80° C. for 30 minutes under nitrogen flow (80 ml/min). While the nitrogen flow rate and the temperature were maintained, a solution obtained by dissolving 10.33 g of methacrylic acid, 3.00 g of methyl methacrylate, and 0.76 g of dimethyl 2,2′-azobis(isobutyrate) in 41.05 g of MFG was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 90° C. and by agitating for 2 hours, whereby 62.2 g of a target polymer (Exemplified Compound: (a-6)) was obtained (solid content: 23.25%).

### Synthesis Example 7

### Synthesis of Specified Polymer

### Exemplified Compound: (a-7)

To a 200-ml three-necked flask, 10.11 g of MFG was added, followed by heating and agitating at 80° C. for 30 minutes under nitrogen flow (80 ml/min). While the nitrogen flow rate and the temperature were maintained, a solution obtained by dissolving 11.62 g of methacrylic acid, 1.50 g of methyl methacrylate, and 0.76 g of dimethyl 2,2′-azobis(isobutyrate) in 40.46 g of MFG was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 90° C. and by agitating for 2 hours, whereby 59.7 g of a target polymer (Exemplified Compound: (a-7)) was obtained (solid content: 23.87%).

### Synthesis Example 8

### Synthesis of Specified Polymer

### Exemplified Compound: (a-8)

To a 200-ml three-necked flask, 14.01 g of MFG was added, followed by heating and agitating at 80° C. for 30 minutes under nitrogen flow (80 ml/min). While the nitrogen flow rate and the temperature were maintained, a solution obtained by dissolving 11.11 g of vinyl benzoate, 7.51 g of methyl methacrylate, and 0.76 g of dimethyl 2,2′-azobis(isobutyrate) in 56.05 g of MFG was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 90° C. and by agitating for 2 hours, whereby 89.8 g of a target polymer (Exemplified Compound: (a-8)) was obtained (solid content: 22.06%).

### Synthesis Example 9

### Synthesis of Specified Polymer

### Exemplified Compound: (a-9)

To a 200-ml three-necked flask, 10.71 g of MFG was added, followed by heating and agitating at 80° C. for 30 minutes under nitrogen flow (80 ml/min). While the nitrogen flow rate and the temperature were maintained, a solution obtained by dissolving 6.46 g of methacrylic acid, 7.51 g of methyl methacrylate, and 0.76 g of dimethyl 2,2′-azobis(isobutyrate) in 42.84 g of MFG was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 90° C. and by agitating for 2 hours. Thereafter, the resultant solution was cooled in an ice bath, and 15 ml of an aqueous solution of NaOH (2N) was added by dropping thereto while the temperature of the mixture was controlled so as not to exceed 10° C. Then, the mixture was agitated so as to be homogeneous, and after that, the mixture was allowed to be room temperature, whereby 78.0 g of a target polymer (Exemplified Compound: (a-9)) was obtained (solid content: 19.38%).

### Synthesis Example 10

### Synthesis of Specified Polymer

### Exemplified Compound: (a-10)

To a 200-ml three-necked flask, 10.71 g of MFG was added, followed by heating and agitating at 80° C. for 30 minutes under nitrogen flow (80 ml/min). While the nitrogen flow rate and the temperature were maintained, a solution obtained by dissolving 6.46 g of methacrylic acid, 7.51 g of methyl methacrylate, and 0.76 g of dimethyl 2,2′-azobis(isobutyrate) in 42.84 g of MFG was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 90° C. and by agitating for 2 hours. Thereafter, the resultant solution was cooled in an ice bath, and 37.5 ml of an aqueous solution of NaOH (2N) was added by dropping thereto while the temperature of the mixture was controlled so as not to exceed 10° C. Then, the mixture was agitated so as to be homogeneous, and after that, the mixture was allowed to be room temperature, whereby 106.3 g of a target polymer (Exemplified Compound: (a-10)) was obtained (solid content: 15.80%).

### Synthesis Example 11

### Synthesis of Comparative Polymer (ac-1)

To a 200-ml three-necked flask, 6.00 g of MFG and 4.00 g of MeOH were added, followed by heating and agitating at 80° C. for 30 minutes under nitrogen flow (80 ml/min). While the nitrogen flow rate and the temperature were maintained, a solution obtained by dissolving 12.91 g of methacrylic acid and 0.76 g of dimethyl 2,2′-azobis(isobutyrate) in a mixture of 23.92 g of MFG and 15.94 g of MeOH was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 85° C. and by agitating for 6 hours, whereby 57.2 g of a polymer (ac-1) having the following structure was obtained (solid content: 24.57%). The polymer had a weight-average molecular weight determined by the GPC method of 29,000.

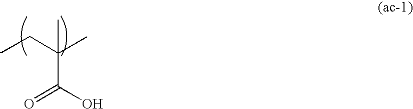

### Synthesis Example 12

### Synthesis of Comparative Polymer (ac-2)

To a 200-ml three-necked flask, 11.31 g of MFG was added, followed by heating and agitating at 80° C. for 30 minutes under nitrogen flow (80 ml/min). While the nitrogen flow rate and the temperature were maintained, a solution obtained by dissolving 1.29 g of methacrylic acid, 13.52 g of methyl methacrylate, and 0.76 g of dimethyl 2,2′-azobis(isobutyrate) in 45.23 g of MFG was added by dropping into the 200-ml three-necked flask over 2 hours, followed by agitating for 4.5 hours. Furthermore, 0.38 g of dimethyl 2,2′-azobis(isobutyrate) was added thereto, followed by heating to 90° C. and agitating for 2 hours, whereby 71.3 g of a polymer (ac-2) having the following structure was obtained (solid content: 22.37%). The polymer had a weight-average molecular weight determined by the GPC method of 30,000.

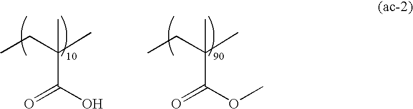

### Synthesis Example 13

### Synthesis of Comparative Polymer (ac-3)

To a 200-ml three-necked flask, 11.16 g of MFG was added, followed by heating and agitating at 80° C. for 30 minutes under nitrogen flow (80 ml/min). While the nitrogen flow rate and the temperature were maintained, a solution obtained by dissolving 2.58 g of methacrylic acid, 12.01 g of methyl methacrylate, and 0.76 g of dimethyl 2,2′-azobis(isobutyrate) in 44.64 g of MFG was added by dropping into the 200-ml three-necked flask over 2 hours, followed by agitating for 4.5 hours. Furthermore, 0.38 g of dimethyl 2,2′-azobis(isobutyrate) was added thereto, followed by heating to 90° C. and agitating for 2 hours, whereby 69.8 g of a polymer (ac-3) having the structure was obtained (solid content: 22.56%). The polymer had a weight-average molecular weight determined by the GPC method of 31,000.

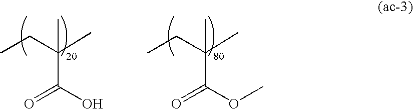

### Synthesis Example 14

### Synthesis of Comparative Polymer (ac-4)

To a 200-ml three-necked flask, 11.46 g of MFG was added, followed by heating and agitating at 80° C. for 30 minutes under nitrogen flow (80 ml/min). While the nitrogen flow rate and the temperature were maintained, a solution obtained by dissolving 15.02 g of methacrylic acid and 0.76 g of dimethyl 2,2′-azobis(isobutyrate) in 45.83 g of MFG was added by dropping into the 200-ml three-necked flask over 2 hours, followed by agitating for 4.5 hours. Furthermore, 0.38 g of dimethyl 2,2′-azobis(isobutyrate) was added thereto, followed by heating to 90° C. and agitating for 2 hours, whereby 73.2 g of a polymer (ac-4) having the following structure was obtained (solid content: 22.08%). The polymer had a weight-average molecular weight determined by the GPC method of 35,000.

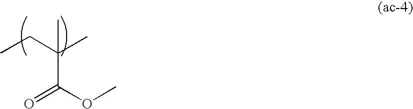

### Synthesis Example 15

### Synthesis of Comparative Polymer (ac-5)

To a 200-ml three-necked flask, 11.87 g of MFG was added, followed by heating and agitating at 80° C. for 30 minutes under nitrogen flow (80 ml/min). While the nitrogen flow rate and the temperature were maintained, a solution obtained by dissolving 1.29 g of methacrylic acid, 5.17 g of methacrylic acid, 6.01 g of methyl methacrylate, 0.76 g of dimethyl 2,2′-azobis(isobutyrate), and an aqueous solution obtained by dissolving 3.11 g of 2-acrylamido-2-methylpropane sulfonic acid in 10 g of water, in 37.42 g of MFG was added by dropping into the 200-ml three-necked flask over 2 hours, followed by agitating for 4.5 hours. Furthermore, 0.38 g of dimethyl 2,2′-azobis(isobutyrate) was added thereto, followed by heating to 90° C. and agitating for 2 hours, whereby 75.2 g of a polymer (ac-5) having the following structure was obtained (solid content: 22.22%). The polymer had a weight-average molecular weight determined by the GPC method of 38,000.

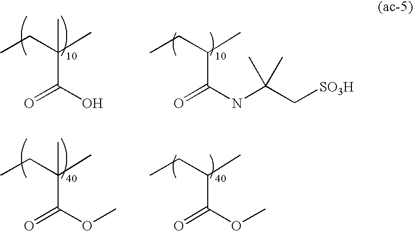

### Synthesis Example 16

### Synthesis of Comparative Polymer (ac-6)

To a 200-ml three-necked flask, 13.29 g of MFG was added, followed by heating and agitating at 80° C. for 30 minutes under nitrogen flow (80 ml/min). While the nitrogen flow rate and the temperature were maintained, a solution obtained by dissolving 1.29 g of methacrylic acid, 5.01 g of methacrylic acid, 0.76 g of dimethyl 2,2′-azobis(isobutyrate), and an aqueous solution obtained by dissolving 12.44 g of 2-acrylamido-2-methylpropane sulfonic acid in 10 g of water in 43.15 g of MFG was added by dropping into the 200-ml three-necked flask over 2 hours, followed by heating and agitating for 4.5 hours. Furthermore, 0.38 g of dimethyl 2,2′-azobis(isobutyrate) was added thereto, followed by heating to 90° C. and agitating for 2 hours, whereby 85.16 g of a polymer (ac-6) having the following structure was obtained (solid content: 22.02%). The polymer had a weight-average molecular weight determined by the GPC method of 40,000.

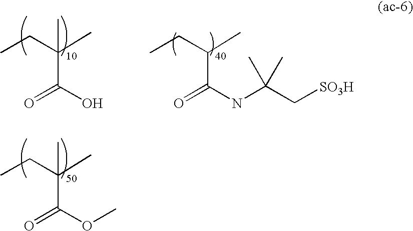

### Synthesis Example 17

### (E) Synthesis of Binder Resin (Acrylic Resin) (E-1)

To a 300-ml three-necked flask provided with a condenser and an agitator, 100 g of N,N-dimethylacetoamide was added, followed by heating a liquid to a temperature of 80° C. after the inside of the flask was replaced with nitrogen in advance. Therein, a solution obtained by dissolving 7 g of allyl methacrylate, 6 g of acrylnitrile, 7 g of N-(4-carboxyphenyl)methacrylamide and 0.4 g of 2,2′-azobisisobutyllonitrile in 80 g of N,N-dimethylacetoamide was dropped over 2 hr. At 1 hr after the end of the dropping, 0.2 g of 2,2′-azobisisobutyllonitrile was added again, followed by heating further for 4 hr. A reaction solution was poured in water of 2 L under agitation and thereby a white polymer was precipitated. The polymer was washed with water and dried in vacuum and thereby a binder resin (E-1) having a repetition unit represented by a formula (E-1) shown below was obtained. A weight average molecular weight by the GPC method was 50000. In the formula below, a numerical value next to ( ) that represents a structural unit represents a polymerization mole ratio (% by mol) of the structural unit.

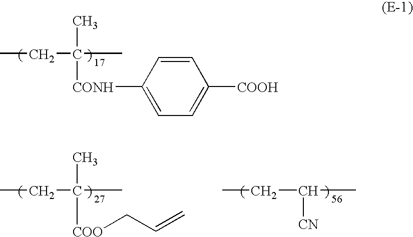

### Examples 1-14

### Comparative Example 1-7

### Preparation of Support

An aluminum plate (JIS A 1050) having a thickness of 0.30 mm and a width of 1,030 mm was subjected to surface treatment as described below.

<Surface Treatment>

Surface treatment was carried out by performing the following treatments (a) to (f) successively. After the treatments and water washing, nip rollers were used to remove liquids.

(a) An aluminum plate was etched with an etching solution (concentration of sodium hydroxide: 26% by mass; concentration of aluminum ions: 6.5% by mass) at 70° C., dissolving the aluminum plate by 5 g/m². Thereafter, the plate was washed with water.

(b) The plate was subjected to a desmutting treatment with a 1% by mass aqueous solution of nitric acid (including 0.5% by mass of aluminum ions) at 30° C. by use of a spray, followed by washing with water.

(c) An electrochemical surface roughening treatment was applied continuously with a 60 Hz AC voltage. At this time, an electrolytic solution was a 1% by mass aqueous solution of nitric acid (including 0.5% by mass of aluminum ion and 0.007% by mass of ammonium ion) and a temperature was 30° C. With a trapezoidal rectangular wave AC of which TP during which a current value reaches from zero to a peak is 2 msec and a duty ratio is 1:1 and with a carbon electrode as a counter electrode, electrochemical surface roughening was carried out. As an auxiliary anode, ferrite was used. A current density was 25 A/dm² at the peak value of the current and an amount of electricity was 250 C/cm² by a sum total of amount of electricity when an aluminum plate was an anode. At this time, 5% of a current from a power source was divided to the auxiliary anode. Thereafter, the aluminum plate was washed with water.

(d) The aluminum plate was subjected to etching treatment by spraying an aqueous solution containing 26% by mass sodium hydroxide and 6.5% by mass aluminum ions at 35° C. Thereby, an amount of 0.2 g/m² of the aluminum plate was dissolved to remove a smut component mainly containing aluminum hydroxide generated when the preceding electrochemical surface roughing treatment was carried out using AC and also to dissolve the edge part of the pit produced thereby to smooth the edge part. Then, the aluminum plate was washed with water.

(e) The plate was subjected to desmutting treatment with a 25% by mass aqueous solution of sulfuric acid (including 0.5% by mass of aluminum ions) at 60° C. by use of a spray. Thereafter, the plate was washed with a water spray.

(f) The plate was subjected to an anodizing treatment for 50 seconds using sulfuric acid (including 0.5% by mass of aluminum ions) at a concentration of 170 g/L, at temperature of 33° C. and a current density of 5 A/dm². Thereafter, the plate was washed with water. At this time, the weight of the anodized layer was 2.7 g/m².

The surface roughness Ra of the thus-obtained aluminum support was 0.27 μm (measurement apparatus: SURFCOM (trade name) manufactured by Tokyo Seimitsu Co., Ltd.; probe tip diameter: 2 μm).

(Undercoat Layer)

Undercoat layer coating solutions having the compositions described below were prepared by using the specified polymers or comparative polymers shown in Table 1. Each of the resultant undercoat layer coating solutions was applied onto the surface-treated aluminum support by means of a wire bar, followed by drying at 90° C. for 30 minutes. The amount of the coating solution applied onto the support was 8 mg/m².

### Undercoat Layer Coating Solution

| | |
|---|---|
| Specified polymer or Comparative Polymer (shown in Table 1) | 0.04 g |
| Methanol | 27 g |
| Ion exchange water | 3 g |

(Photosensitive Layer)

A photosensitive layer coating solution shown below was prepared and coated on an aluminum support on which the undercoat layer was coated by use of a wire bar. A hot air dryer was used at 115° C. for 34 sec to dry. A dry coated amount after drying was from 1.4 to 2.0 g/m².

### [Photosensitive Layer Coating Solution]

| | |
|---|---|
| Binder resin (E-1) | 1.00 g |
| Infrared absorbent (A-1): structure shown below | 0.074 g |
| Organoboron compound (compound shown in Table 1) | 0.300 g |
| Onium salt compound (compound shown in Table 1) | 0.161 g |
| Polymerizable compound (pentaerythritol hexaacrylate) | 1.00 g |
| Colorant (CL-1): structure shown below | 0.04 g |
| Fluorinated surfactant (trade name: MEGAFAC F-780-F, | 0.016 g |
| manufactured by Dainippon Ink & Chemicals, Incorporated, | |
| 30% by mass of methyl isobutyl ketone (MIBK)) | |
| Methyl ethyl ketone | 10.4 g |
| Methanol | 5.16 g |
| 1-methoxy-2-propanol | 10.4 g |

The (E) binder resin (E-1) is a compound obtained in the synthesis example 17. Structures of the (A) infrared absorbent (A-1), (B) organoboron compounds (B-1) through (B-3), (C) onium salt compounds (C-9) through (C-11) and colorant (CL-1) shown in Table 1 are shown below.

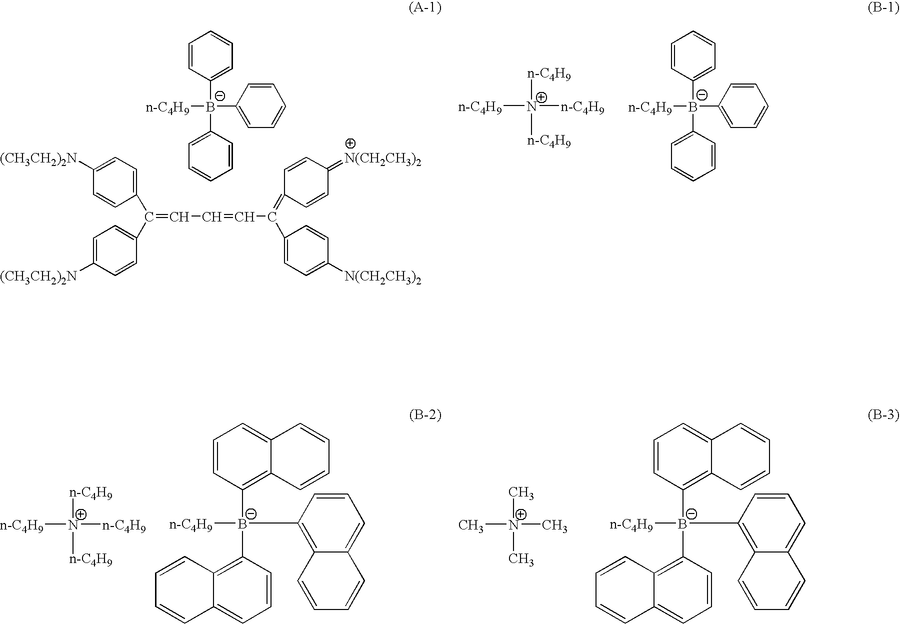

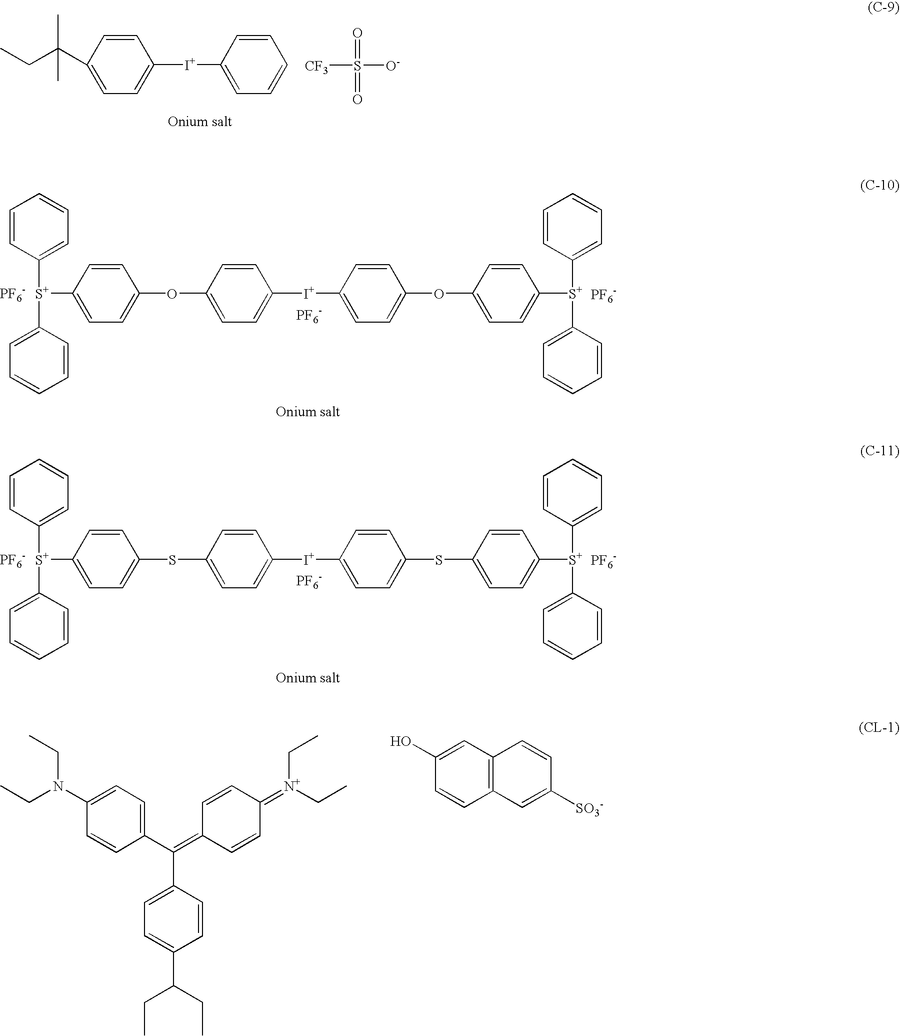

(Evaluation of Planographic Printing Plate Precursor)

### (1) Evaluation of Sensitivity

With an exposure device (TRENDSETTER 3244VX (trade name, manufactured by Creo Inc.) equipped with a water-cooled 40 W infrared semiconductor laser), each of the resultant planographic printing plate precursors was exposed to light under the following conditions: the resolution was 175 lpi, the rotation speed of the outer face drum was 150 rpm, the output was in the range of from 0 to 8 W, the output being changed in increments of 0.15 as a value of log e within the above output range, the temperature was 25° C., and the relative humidity was 50%. After the exposure, washing with tap water was conducted to remove the protective layer, followed by development at 30° C. for 12 seconds by use of a LP-1310HII (trade name, by Fuji Photo Film Co., Ltd.). The developer used in the development was a solution obtained by diluting a developing agent DV-2 (trade name, manufactured by Fuji Photo Film Co., Ltd.) with water at a dilution ratio of 1:4, and the finisher used in the development was a solution obtained by diluting a finisher agent GN-2K (trade name, manufactured by Fuji Photo Film Co., Ltd.) with water at a dilution ratio 1:1.

Regarding the density of the image portion of a planographic printing plate obtained by the development, a Macbeth reflection densitometer (trade name: RD-918) was used to measure the cyan density of the image portion through a red filter equipped on the densitometer. The reciprocal number of the exposure dose necessary for making the measured density 0.8 was used as an index of sensitivity. The sensitivity of the plate of Example 1 was regarded as 100, and the sensitivity of each of the other planographic printing plates was represented in terms of a relative value thereto. A larger value indicates a higher sensitivity. The evaluation results are shown in Table 1.

### (2) Evaluation of Raw Stock Storability (Evaluation of Aging Stability)

An unexposed planographic printing plate precursor was stored under 45° C. and 75% RH for 3 days, followed by exposing and developing according to a method shown below, and the density of a non-image area was measured by use of a Macbeth Reflection densitometer RD-918 (trade name). A planographic printing plate precursor immediately after preparation as well was exposed and developed in a similar manner and the density of a non-image area was measured. In the present example, a difference A of the densities of the non-image areas thereof was obtained and used as an indicator of the raw stock storability. The smaller the value of A is, the better the raw stock storability is. When the difference is 0.02 or less, the raw stock storability is a level causing no problems in practical use. Results are shown in Table 1.

(Exposure and Development)

Each of the resultant planographic printing plate precursors was mounted on the exposure device (TRENDSETTER 3244VX (trade name, manufactured by Creo Inc.) equipped with a water-cooled 40 W infrared semiconductor laser), and exposed to a solid density image having a resolution of 175 lpi under an output of 8 W, a rotation speed of the outer face drum of 206 rpm, and a plate surface energy of 100 mJ/cm². After the exposure, washing with tap water was conducted to remove the protective layer, followed by development according to the same method as that of the development process used in the (1) Evaluation of sensitivity section.

### (3) Evaluation of Printing Durability and Stain Resistance

Each of the resultant planographic printing plate precursors was mounted on the exposure device (TRENDSETTER 3244VX (trade name, manufactured by Creo Inc.), and exposed to a 80% flat tint image having a resolution of 175 lpi under an output of 8 W, a rotation speed of the outer face drum of 206 rpm, and a plate surface energy of 100 mJ/cm². After the exposure, washing with tap water was conducted to remove the protective layer, followed by development according to the same method as that of the development process used in the (1) Evaluation of sensitivity section. The resultant planographic printing plate was used for printing with a printer LITHRON (trade name, manufactured by Komori Corporation), and ink that was present on the surface of the plate was removed repeatedly every 10,000 prints, with a multi-cleaner (trade name, manufactured by Fuji Photo Film Co., Ltd.). The number of printed sheets was used as an index of the printing durability. A larger value indicates a better printing durability. Results are shown in Table 1.

Furthermore, at the time of evaluation of the printing durability, ink stain of a non-image area was visually evaluated based on ten levels as the printing stain resistance (before accelerated aging test). Furthermore, a planographic printing plate precursor undergone the accelerated aging test by storing for 3 days under 45° C. and 75% RH as well was evaluated according to a similar manner (after the accelerated aging test). The larger the numerical value is, the more excellent the stain resistance is. An evaluation of 8 or more is practical level and an evaluation of 6 is the lowest acceptable level. Results are shown in Table 1.

TABLE 1

| | Specified | | | | | | | Printing stain | |
|---|---|---|---|---|---|---|---|---|---|
| | polymer for | | | | | | | resistance | |
| | undercoat | | | | | | | Before | After |
| | agent or | (A) | (B) | (C) | | Raw stock | Printing | accelerated | accelerated |
| | comparative | Infrared | Organoboron | Onium salt | | storability | durability | aging | aging |
| | polymer | absorbent | compound | compound | Sensitivity | Δfog | (sheets) | test | test |
| Example 1 | a-1 | A-1 | B-1 | C-9 | 100 | 0 | 100,000 | 8 | 8 |
| Example 2 | a-1 | A-1 | B-2 | C-9 | 110 | 0 | 120,000 | 8 | 8 |
| Example 3 | a-1 | A-1 | B-3 | C-9 | 110 | 0 | 110,000 | 8 | 8 |
| Example 4 | a-1 | A-1 | B-1 | C-10 | 120 | 0 | 120,000 | 8 | 8 |
| Example 5 | a-1 | A-1 | B-1 | C-11 | 120 | 0 | 120,000 | 8 | 8 |
| Example 6 | a-2 | A-1 | B-1 | C-9 | 100 | 0 | 100,000 | 9 | 8 |
| Example 7 | a-3 | A-1 | B-1 | C-9 | 100 | 0 | 100,000 | 10 | 10 |
| Example 8 | a-4 | A-1 | B-1 | C-9 | 100 | 0 | 100,000 | 10 | 10 |
| Example 9 | a-5 | A-1 | B-1 | C-9 | 100 | 0 | 100,000 | 10 | 10 |
| Example 10 | a-6 | A-1 | B-1 | C-9 | 100 | 0 | 100,000 | 10 | 10 |
| Example 11 | a-7 | A-1 | B-1 | C-9 | 100 | 0 | 90,000 | 10 | 10 |
| Example 12 | a-8 | A-1 | B-1 | C-9 | 100 | 0 | 120,000 | 8 | 7 |
| Example 13 | a-9 | A-1 | B-1 | C-9 | 100 | 0 | 110,000 | 10 | 10 |
| Example 14 | a-10 | A-1 | B-1 | C-9 | 100 | 0 | 100,000 | 10 | 10 |
| Comparative | a-1 | A-1 | B-1 | None | 15 | 0 | ≦10,000 | 10 | 10 |
| Example 1 | | | | | | | | | |
| Comparative | a-1 | A-1 | None | C-9 | 15 | 0 | ≦10,000 | 10 | 10 |
| Example 2 | | | | | | | | | |
| Comparative | ac-1 | A-1 | B-1 | C-9 | 100 | 0 | 50,000 | 5 | 4 |
| Example 3 | | | | | | | | | |
| Comparative | ac-2 | A-1 | B-1 | C-9 | 100 | 0 | 100,000 | 4 | 4 |
| Example 4 | | | | | | | | | |
| Comparative | ac-3 | A-1 | B-1 | C-9 | 100 | 0 | 100,000 | 5 | 4 |
| Example 5 | | | | | | | | | |
| Comparative | ac-4 | A-1 | B-1 | C-9 | 100 | 0 | 100,000 | 2 | 1 |
| Example 6 | | | | | | | | | |
| Comparative | ac-5 | A-1 | B-1 | C-9 | 100 | 0 | 80,000 | 3 | 2 |
| Example 7 | | | | | | | | | |

As is obvious from the Table 1, according to the negative-working photosensitive material of the invention, the developability in a non-image area and the adhesiveness with a substrate are improved, both stain resistance and printing durability in the printing are concurrently achieved, and high-sensitivity recording is realized; accordingly, in particular, it is found that an excellent planographic printing plate can be provided without providing an oxygen-blocking layer.

On the other hand, in comparative examples 1 and 2 where only either (B) an organoboron compound or (C) an onium compound is contained as the polymerization initiator in a photosensitive layer, it is found that high-sensitivity is not achieved and, since the image area strength is also insufficient, the printing durability is poor. Furthermore, even when the photosensitive layer contains the specified compound group according to the invention, in comparative examples 3 through 7 where the specified polymer according to the invention is not contained in the undercoat layer, stain resistance in printing is inferior, and both printing durability and stain resistance cannot be concurrently achieved.

The invention includes the following embodiments.
<1> A negative-working photosensitive material formed by sequentially layering an undercoat layer and a photosensitive layer on a support, wherein:

the undercoat layer contains a polymer containing (a) a structural unit containing at least one selected from a carboxylic acid or a carboxylic acid salt and (b) a structural unit containing at least one carboxylic acid ester:

the photosensitive layer contains (A) an infrared absorbent, (B) an organoboron compound, (C) an onium salt compound and (D) a compound having a polymerizable unsaturated group: and

a ratio of (a) the structural unit containing at least one selected from a carboxylic acid or a carboxylic acid salt in the polymer containing (a) the structural unit containing at least one selected from a carboxylic acid or a carboxylic acid salt and (b) the structural unit containing at least one carboxylic acid ester is 30 to 90% by mol.

<2> The negative-working photosensitive material of <1>, wherein the polymer containing (a) the structural unit containing at least one selected from a carboxylic acid or a carboxylic acid salt and (b) the structural unit containing at least one carboxylic acid ester does not substantially contain an acid other than carboxylic acid.
<3> The negative-working photosensitive material of <1> or <2>, wherein (A) the infrared absorbent is a near-infrared absorbing dye represented by the following formula (1):

D⁺A⁻ Formula (1)

wherein in the formula (1), D⁺ represents a cationic dye having a color developing atomic group having an absorption in a near-infrared region and A⁻ represents a counter anion.

<4> The negative-working photosensitive material of any one of <1> through <3>, wherein (B) the organoboron compound is a compound represented by the following formula (2): 08]

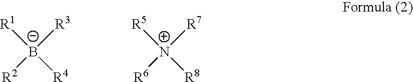

wherein in the formula (2), R¹, R², R³ and R⁴ each independently represent an alkyl group, an aryl group, an alkaryl group, an allyl group, an aralkyl group, an alkenyl group, an alkynyl group, an alicyclic group, or a saturated of unsaturated heterocyclic group, at least one of R¹, R², R³ or R⁴ is an alkyl group having 1 to 8 carbon atoms.

R⁵, R⁶, R⁷ and R⁸ each independently represent a hydrogen atom, an alkyl group, an aryl group, an allyl group, an alkaryl group, an aralkyl group, an alkenyl group, an alkynyl group, an alicyclic group, or a saturated or unsaturated heterocyclic group.

<5> The negative-working photosensitive material of any one of <1> through <4> wherein (C) the onium salt compound is at least one selected from sulfonium salt compounds or iodonium salt compounds.
<6> The negative-working photosensitive material of any one of <1> through <4>, wherein (C) the onium salt compound is a compound having at least two different onium ions in a molecule.
<7> The negative-working photosensitive material of <6>, wherein the onium ions are S⁺ and I⁺.
<8> The negative-working photosensitive material of any one of <1> through <4>, wherein (C) the onium salt compound contains an aromatic ring having a substituent group in a molecule.
<9> The negative-working photosensitive material of any one of <1> through <5>, wherein the photosensitive layer further contains (E) a binder resin.
<10> The negative-working photosensitive material of <9>, wherein (E) the binder resin is a resin containing an alkali-soluble resin.
<11> The negative-working photosensitive material of <9> or <10>, wherein (E) the binder resin is a resin containing a polymer having an aromatic carboxyl group.
<12> A negative-working planographic printing plate precursor formed with the negative-working photosensitive material of any one of <1> through <11>.
All publications, patent applications, and technical standards mentioned in this specification are herein incorporated by reference to the same extent as if each individual publication, patent application, or technical standard was specifically and individually indicated to be incorporated by reference.

What is claimed is:

1. A negative-working photosensitive material formed by sequentially layering an undercoat layer and a photosensitive layer on a support, wherein:
the undercoat layer contains a polymer containing (a) a structural unit containing at least one selected from a carboxylic acid or a carboxylic acid salt and (b) a structural unit containing at least one carboxylic acid ester;
the photosensitive layer contains (A) an infrared absorbent, (B) an organoboron compound, (C) an onium salt compound and (D) a compound having a polymerizable unsaturated group; and
a ratio of (a) the structural unit containing at least one selected from a carboxylic acid or a carboxylic acid salt in the polymer containing (a) the structural unit containing at least one selected from a carboxylic acid or a carboxylic acid salt and (b) the structural unit containing at least one carboxylic acid ester is 30 to 90% by mol.

2. The negative-working photosensitive material of claim 1, wherein the polymer containing (a) the structural unit containing at least one selected from a carboxylic acid or a carboxylic acid salt and (b) the structural unit containing at least one carboxylic acid ester does not substantially contain an acid other than carboxylic acid.

3. The negative-working photosensitive material of claim 1, wherein (A) the infrared absorbent is a near-infrared absorbing dye represented by the following formula (1):
D⁺A⁻ Formula (1)
wherein in the formula (1), D⁺ represents a cationic dye having a color developing atomic group having an absorption in a near-infrared region, and A⁻ represents a counter anion.

4. The negative-working photosensitive material of claim 1, wherein (B) the organoboron compound is a compound represented by the following formula (2): 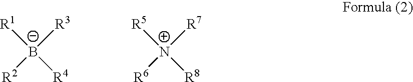
wherein in the formula (2), R¹, R², R³ and R⁴ each independently represent an alkyl group, an aryl group, an alkaryl group, an allyl group, an aralkyl group, an alkenyl group, an alkynyl group, an alicyclic group, or a saturated of unsaturated heterocyclic group, at least one of R¹, R², R³ or R⁴ being an alkyl group having 1 to 8 carbon atoms; and
R⁵, R⁶, R⁷ and R⁸ each independently represent a hydrogen atom, an alkyl group, an aryl group, an allyl group, an alkaryl group, an aralkyl group, an alkenyl group, an alkynyl group, an alicyclic group, or a saturated or unsaturated heterocyclic group.

5. The negative-working photosensitive material of claim 1, wherein (C) the onium salt compound is at least one selected from a sulfonium salt compound or an iodonium salt compound.

6. The negative-working photosensitive material of claim 1, wherein (C) the onium salt compound is a compound having at least two different onium ions in a molecule.

7. The negative-working photosensitive material of claim 6, wherein the onium ions are S⁺ and I⁺.

8. The negative-working photosensitive material of claim 1, wherein (C) the onium salt compound contains an aromatic ring having a substituent group in a molecule.

9. The negative-working photosensitive material of claim 1, wherein the photosensitive layer further contains (E) a binder resin.

10. The negative-working photosensitive material of claim 9, wherein (E) the binder resin is a resin containing an alkali-soluble resin.

11. The negative-working photosensitive material of claim 9, wherein (E) the binder resin is a resin containing a polymer having an aromatic carboxyl group.

12. A negative-working planographic printing plate precursor formed with the negative-working photosensitive material of claim 1.
